(19) United States
(12) Patent Application Publication
(10) Pub. No.: US 2025/0120011 A1
(43) Pub. Date: Apr. 10, 2025

(54) ELECTRONIC ELEMENT ASSEMBLY, IMAGE SENSOR MODULE, CAMERA MODULE AND ELECTRONIC DEVICE

(71) Applicant: Largan Industrial Optics Co., Ltd., Taichung City (TW)

(72) Inventors: Ti Lun LIU, Taichung City (TW); Kai-Chien HSU, Taichung City (TW); Chien Yen CHEN, Taichung City (TW); Yu-Chen LAI, Taichung City (TW); Ming-Ta CHOU, Taichung City (TW)

(21) Appl. No.: 18/899,151

(22) Filed: Sep. 27, 2024

Related U.S. Application Data
(60) Provisional application No. 63/588,311, filed on Oct. 6, 2023.

(51) Int. Cl. H05K 1/02

(52) U.S. Cl. CPC H05K 1/0281; H05K 1/0298; H05K 2201/057; H05K 2201/10121; H05K 2201/10151; H05K 2201/10818

(57) ABSTRACT

An electronic element assembly includes a first electronic element, an electronic element board and a flexible circuit. The first electronic element is disposed on the electronic element board, and the electronic element board includes a first circuit and a second circuit, wherein the first circuit and the second circuit are disposed on relative sides of the first electronic element, respectively. The flexible circuit is disposed on the electronic element board, and the flexible circuit includes a connecting portion, a bending portion and an electronic path. The connecting portion is connected to the electronic element board. The bending portion is disposed on a side of the connecting portion away from the first electronic element. At least one portion of the electronic path is disposed on the bending portion.

### RELATED APPLICATIONS

This application claims priority to U.S. Provisional Application Ser. No. 63/588,311 filed Oct. 6, 2023, which is herein incorporated by reference.

### BACKGROUND

### Technical Field

The present disclosure relates to an electronic element assembly, an image sensor module and a camera module. More particularly, the present disclosure relates to an electronic element assembly, an image sensor module and a camera module applicable to portable electronic devices.

### Description of Related Art

In recent years, portable electronic devices have developed rapidly. For example, intelligent electronic devices and tablets have been filled in the lives of modern people, and camera modules, image sensor modules and electronic element assemblies thereof mounted on portable electronic devices have also prospered. However, as technology advances, the quality requirements of the electronic element assembly are becoming higher and higher. Therefore, an electronic element assembly, which can achieve the circuit structure with the extreme dimension so as to enhance the design density, needs to be developed.

### SUMMARY

According to one aspect of the present disclosure, an electronic element assembly includes a first electronic element, an electronic element board and a flexible circuit. The first electronic element is disposed on the electronic element board, and the electronic element board includes a first circuit and a second circuit, wherein the first circuit and the second circuit are disposed on relative sides of the first electronic element, respectively, and the first circuit is electronically connected to the first electronic element. The flexible circuit is disposed on the electronic element board, and the flexible circuit includes a connecting portion, a bending portion and an electronic path. The connecting portion is connected to the electronic element board. The bending portion is disposed on a side of the connecting portion away from the first electronic element, and the bending portion bends along a thickness direction of the electronic element board. The electronic path includes a first end and a second end, and at least one portion of the electronic path is disposed on the bending portion, wherein the first end is electronically connected to the first circuit, the second end is electronically connected to the second circuit, and the first end and the second end are disposed on the connecting portion.

According to one aspect of the present disclosure, an image sensor module includes the electronic element assembly of the aforementioned aspect, wherein the first electronic element is an image sensor.

According to one aspect of the present disclosure, a camera module includes the image sensor module of the aforementioned aspect and an imaging lens assembly, wherein the imaging lens assembly is relatively disposed to the image sensor.

According to one aspect of the present disclosure, an electronic device includes the camera module of the aforementioned aspect.

According to one aspect of the present disclosure, an electronic element assembly includes a first electronic element, a second electronic element, an electronic element board and a flexible circuit. The first electronic element and the second electronic element are disposed at interval. The first electronic element and the second electronic element are disposed on the electronic element board. The flexible circuit is disposed on the electronic element board, and the flexible circuit includes a connecting portion, a bending portion and an electronic path. The connecting portion is connected to the electronic element board. The bending portion is disposed on a side of the connecting portion away from the first electronic element and the second electronic element, and the bending portion bends along a thickness direction of the electronic element board. The electronic path includes a first end and a second end, and at least one portion of the electronic path is disposed on the bending portion, wherein the first end is electronically connected to the first electronic element, the second end is electronically connected to the second electronic element, and the first end and the second end are disposed on the connecting portion.

According to one aspect of the present disclosure, an image sensor module includes the electronic element assembly of the aforementioned aspect, wherein the first electronic element is an image sensor.

According to one aspect of the present disclosure, a camera module includes the image sensor module of the aforementioned aspect and an imaging lens assembly, wherein the imaging lens assembly is relatively disposed to the image sensor.

According to one aspect of the present disclosure, an electronic device includes the camera module of the aforementioned aspect.

### BRIEF DESCRIPTION OF THE DRAWINGS

FIG. 1A is a three-dimensional view of a camera module according to the 1 st embodiment of the present disclosure.

FIG. 1B is an exploded view of the camera module according to the 1st embodiment in FIG. 1A.

FIG. 1C is a cross-sectional view of the camera module according to the 1st embodiment in FIG. 1A.

FIG. 1D is an exploded view of the image sensor module according to the 1st embodiment in FIG. 1A.

FIG. 1E is a top view of the camera module according to the 1st example of the 1st embodiment in FIG. 1A.

FIG. 1F is a top view of the camera module according to the 2nd example of the 1st embodiment in FIG. 1A.

FIG. 1G is a top view of the camera module according to the 3rd example of the 1st embodiment in FIG. 1A.

FIG. 1H is a top view of the camera module according to the 4th example of the 1st embodiment in FIG. 1A.

FIG. 1I is a top view of the camera module according to the 5th example of the 1st embodiment in FIG. 1A.

FIG. 1J is a top view of the camera module according to the 6th example of the 1st embodiment in FIG. 1A.

FIG. 2A is a three-dimensional view of a camera module according to the 2nd embodiment of the present disclosure.

FIG. 2B is an exploded view of the camera module according to the 2nd embodiment in FIG. 2A.

FIG. 2C is a schematic view of a range of an imaging light path of the camera module according to the 2nd embodiment in FIG. 2A.

FIG. 2D is a cross-sectional view of the camera module according to the 1st example of the 2nd embodiment in FIG. 2A.

FIG. 2E is a schematic view of the image sensor module according to the 1 st example of the 2nd embodiment in FIG. 2A.

FIG. 2F is a three-dimensional view of the camera module according to the 2nd example of the 2nd embodiment in FIG. 2A.

FIG. 3A is a three-dimensional view of a camera module according to the 3rd embodiment of the present disclosure.

FIG. 3B is a partial cross-sectional view of the camera module according to the 3rd embodiment in FIG. 3A.

FIG. 3C is an exploded view of the camera module according to the 3rd embodiment in FIG. 3A.

FIG. 3D is an exploded view of the image sensor module according to the 3rd embodiment in FIG. 3A.

FIG. 3E is a partial enlarged view of the camera module according to the 3rd embodiment in FIG. 3A.

FIG. 4A is a three-dimensional view of a camera module according to the 4th embodiment of the present disclosure.

FIG. 4B is an exploded view of the camera module according to the 4th embodiment in FIG. 4A.

FIG. 4C is a partial enlarged view of the camera module according to the 4th embodiment in FIG. 4B.

FIG. 4D is an exploded view of the image sensor module according to the 4th embodiment in FIG. 4A.

FIG. 4E is a partial exploded view of the image sensor module according to the 4th embodiment in FIG. 4A.

FIG. 4F is a top view of the image sensor module according to the 4th embodiment in FIG. 4A.

FIG. 4G is a partial enlarged view of the image sensor module according to the 4th embodiment in FIG. 4F.

FIG. 5A is a three-dimensional view of a camera module according to the 5th embodiment of the present disclosure.

FIG. 5B is a schematic view of the camera module according to the 5th embodiment in FIG. 5A.

FIG. 5C is a cross-sectional view of the camera module according to the 5th embodiment in FIG. 5A.

FIG. 5D is a partial enlarged view of the camera module according to the 5th embodiment in FIG. 5C.

FIG. 5E is another schematic view of the camera module according to the 5th embodiment in FIG. 5A.

FIG. 5F is an exploded view of the camera module according to the 5th embodiment in FIG. 5A.

FIG. 5G is a top view of the image sensor module according to the 5th embodiment in FIG. 5A.

FIG. 5H is a partial enlarged view of the image sensor module according to the 5th embodiment in FIG. 5A.

FIG. 6A is a three-dimensional view of an electronic device according to the 6th embodiment of the present disclosure.

FIG. 6B is a schematic view of the electronic device according to the 6th embodiment in FIG. 6A.

FIG. 7 is a schematic view of an electronic device applied to a drone according to the 7th embodiment of the present disclosure.

FIG. 8 is a schematic view of an electronic device applied to a car according to the 8th embodiment of the present disclosure.

FIG. 9 is a schematic view of an electronic device applied to a computer according to the 9th embodiment of the present disclosure.

FIG. 10 is a schematic view of an electronic device applied to a wearable device according to the 10th embodiment of the present disclosure.

### DETAILED DESCRIPTION

The present disclosure provides an electronic element assembly, which includes a first electronic element, an electronic element board and a flexible circuit, wherein the first electronic element is disposed on the electronic element board, and the flexible circuit is disposed on the electronic element board. The flexible circuit includes a connecting portion, a bending portion and an electronic path, wherein the connecting portion is connected to the electronic element board, the bending portion is disposed on a side of the connecting portion away from the first electronic element, the bending portion bends along a thickness direction of the electronic element board, and at least one portion of the electronic path is disposed on the bending portion. The electronic path includes a first end and a second end, wherein the first end and the second end are disposed on the connecting portion. The solution of cooperation between the flexible circuit, which is bent, and the electronic element board is favorable for achieving the circuit structure of the extreme dimension, so that the design density of the electronic element assembly can be enhanced, and the structure of the multifunction module or the multi-lens module can be further achieved.

In particular, the electronic element board is configured to support the first electronic element, at least one function of the mechanical strength support, the circuit disposition, the anti-electromagnetic interference or the grounding can be further obtained, but the present disclosure is not limited thereto. By bending the bypass design of the flexible circuit, the degree of freedom of the wiring of the electronic element board can be promoted, so that the volume of the electronic element assembly can be reduced. Furthermore, the flexible circuit extends from the electronic element board and back to the electronic element board so as to achieve the design of the electronic path.

Moreover, the flexible circuit can be obtained via the flexible printed circuit (FPC) or the multilayer circuit board, but the present disclosure is not limited thereto. The electronic element board can be the printed electronic element board or the ceramic electronic element board, and the electronic element board can be further integrated with the flexible circuit by the injection molding.

The electronic element board can include a first circuit and a second circuit, wherein the first circuit and the second circuit are disposed on relative sides of the first electronic element, respectively, the first circuit is electronically connected to the first electronic element, the first end is electronically connected to the first circuit, and the second end is electronically connected to the second circuit. In particular, the electronic path can be away from the first electronic element via the flexible circuit, so that the magnetic effect of the electric current, which is caused via the circuit, can be avoided influencing the electronic element. Therefore, the volume is minimized while maintaining the working status of the electronic element, and the design of the electronic element board can be simplified via the flexible circuit so as to shorten the design period and promote the manufacturing efficiency.

The electronic element assembly can further include a second electronic element, wherein the first electronic element and the second electronic element are disposed at interval, the second electronic element is disposed on the electronic element board, the bending portion is disposed on a side of the connecting portion away from the second electronic element, the first end is electronically connected to the first electronic element, the second end is electronically connected to the second electronic element, and the second electronic element is electronically connected to the second circuit. Furthermore, the electronic element board can further include a third circuit, wherein the third circuit is electronically connected to the first electronic element and the second electronic element. In particular, the first electronic element is connected to the second electronic element via a plurality of intercommunication methods, so that the concentrated load can be avoided to reduce the entire dimension.

The bending portion and the electronic element board can be fixed. Therefore, the signal interference, which is caused by shake, can be avoided by fixing the bending portion.

The electronic element assembly can further include a hardness reinforcing board disposed on the bending portion, and the hardness reinforcing board and the electronic element board are fixed. Therefore, the rigidity of the bending portion can be enhanced via the hardness reinforcing board so as to avoid the damage. Moreover, the hardness reinforcing board can be a metal element so as to shield the electromagnetic interference (EMI), and the hardness reinforcing board can be further combined with the bending portion to form a composite board.

The electronic element board can further include a bend guiding structure correspondingly disposed to a side of the bending portion connected to the connecting portion, and the bending portion bends along the bend guiding structure. Therefore, the degree of emerging of the bending portion from the surface can be reduced so as to enhance the assembling quality.

A dimension of the bending portion on the thickness direction of the electronic element board can be less than or equal to a dimension of the bending portion vertical to the thickness direction of the electronic element board and vertical to a thickness direction of the bending portion. Therefore, the mechanical strength of the bending portion after bending can be ensured.

The bending portion can include a bending auxiliary hole disposed on a side of the bending portion close to the electronic element board, and the electronic path surrounds the bending auxiliary hole. A dimension of the bending auxiliary hole on the thickness direction of the electronic element board can be less than or equal to a dimension of the bending auxiliary hole vertical to the thickness direction of the electronic element board and vertical to a thickness direction of the bending portion. Therefore, the unpredictable deformation of the electronic path during bending can be avoided so as to protect the electronic path.

The electronic element assembly can further include a shape maintaining element correspondingly disposed to a side of the bending portion connected to the connecting portion, and the shape maintaining element and the electronic element board are fixed. Therefore, the damage, which is caused by the collision during assembling, can be avoided, so that the assembling process can be improved. In detail, the shape maintaining element can be a holder.

The connecting portion of the flexible circuit can include a window relatively disposed to the first electronic element. Therefore, the first electronic element can be avoided being blocked via the flexible circuit, so that the first electronic element can have the functions as the photosensitivity and the heat dissipation.

The electronic element assembly can further include a multilayer circuit board, wherein the multilayer circuit board can include the electronic element board and the flexible circuit, and the flexible circuit extends from the electronic element board towards a direction away from the first electronic element.

The electronic element board can further include an element corresponding hole, wherein the first electronic element is disposed on the element corresponding hole. Therefore, the height difference between the first electronic element and the electronic element board can be lowered so as to avoid the interference between the flexible circuit and the gold wire on the first electronic element. Further, the electronic element board can further include a substrate and a circuit layer, wherein the first electronic element is disposed on the substrate, and the first electronic element is electronically connected to the circuit layer.

The electronic element board can further include a contacting point, and the electronic path can include a first sub-path and a second sub-path, wherein the first sub-path is electronically connected to the first circuit, the second sub-path is electronically connected to the second circuit, and the first sub-path and the second sub-path are electronically connected via the contacting point. Therefore, the stability of the flexible circuit can be further enhanced. In particular, each of the first sub-path and the second sub-path can be a gold wire, so that the wiring process can be finished at once.

The bending portion does not include other electronic element. In particular, the first electronic element can include a passive element, a sensing element, a coil, and so on, so that the signal interference can be avoided.

Each of the aforementioned features of the electronic element assembly can be utilized in various combinations for achieving the corresponding effects.

The present disclosure provides an image sensor module, which includes the aforementioned electronic element assembly, wherein the first electronic element is an image sensor.

The image sensor module can further include a holder, wherein the holder includes a through hole, the through hole is correspondingly disposed to the image sensor, and the bending portion is disposed on the holder.

The electronic element assembly can further include a hardness reinforcing board disposed on the bending portion, and the hardness reinforcing board and the holder are fixed.

The holder can further include a bend guiding structure correspondingly disposed to a side of the bending portion connected to the connecting portion, and the bending portion bends along the bend guiding structure.

The window can be relatively disposed to a sensing surface of the image sensor, wherein the flexible circuit is opaque, the window can include a plurality of protrusions tapered towards a direction close to the sensing surface, and a length of each of the protrusions along a direction close to the image sensor can be between 0.08 mm and 0.43 mm. Therefore, the glare caused by the contacting point of the circuit can be blocked via the flexible circuit, and the glare caused by reflecting from the window to the sensing surface can be further avoided via the protrusions. Moreover, the protrusions are tapered on a direction parallel to the sensing surface, and the protrusions can be further tapered on a direction vertical to the sensing surface. The anti-glare structure can include the plurality of the protrusions continuously disposed along the window.

Each of the aforementioned features of the image sensor module can be utilized in various combinations for achieving the corresponding effects.

The present disclosure provides a camera module, which includes the aforementioned image sensor module and an imaging lens assembly, wherein the imaging lens assembly is relatively disposed to the image sensor. In detail, the camera module can further have the functions as focus, zoom, image stabilization, and the aforementioned driving functions can be obtained via the holder of the imaging lens assembly, the imaging lens assembly or the cooperation with each other, but the present disclosure is not limited thereto.

An imaging lens assembly height of the imaging lens assembly is defined from the image sensor towards the thickness direction of the electronic element board, and a bending portion height of the bending portion of the flexible circuit is defined from the image sensor towards the thickness direction of the electronic element board, wherein the imaging lens assembly height can be larger than or equal to the bending portion height.

The electronic element assembly can further include a hardness reinforcing board disposed on the bending portion, and the hardness reinforcing board and the imaging lens assembly are fixed.

The imaging lens assembly can include a bend guiding structure correspondingly disposed to a side of the bending portion connected to the connecting portion, and the bending portion bends along the bend guiding structure.

The bending portion of the flexible circuit can be opaque, and the bending portion can include a blocking area, wherein the blocking area is disposed on a side of the bending portion away from the connecting portion, and the blocking area is correspondingly disposed to an image height of the imaging lens assembly. Therefore, the non-imaging light can be blocked to enter the imaging lens assembly to form the glare so as to enhance the optical quality.

Each of the aforementioned features of the camera module can be utilized in various combinations for achieving the corresponding effects.

The present disclosure provides an electronic device, which includes the aforementioned camera module.

According to the aforementioned embodiment, specific embodiments and examples are provided, and illustrated via figures.

### 1st Embodiment

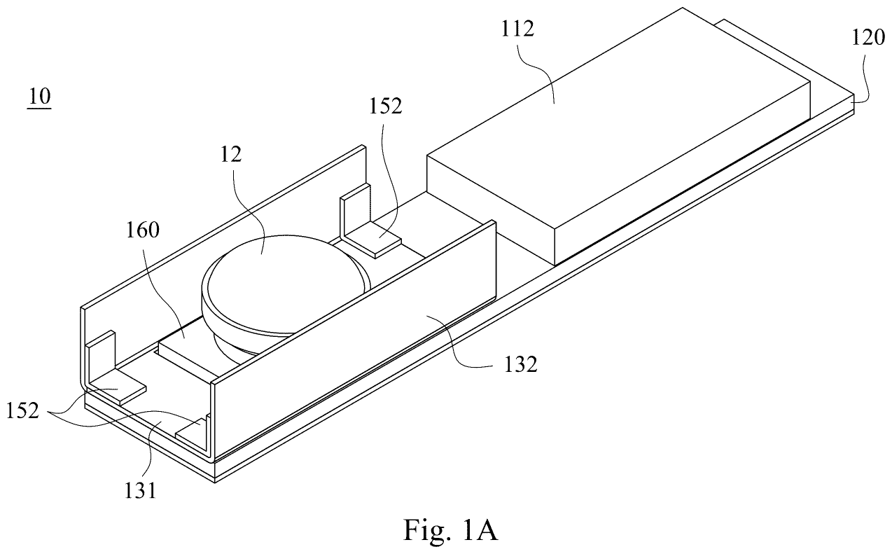

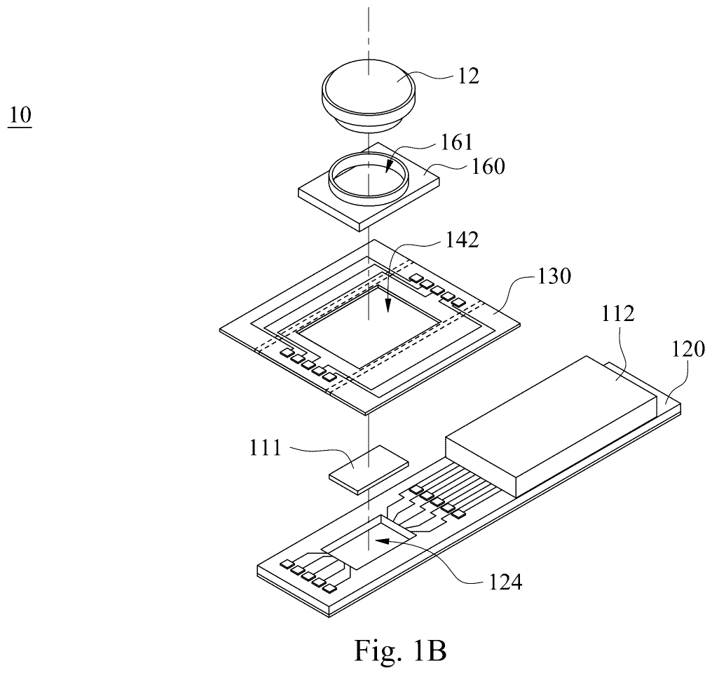

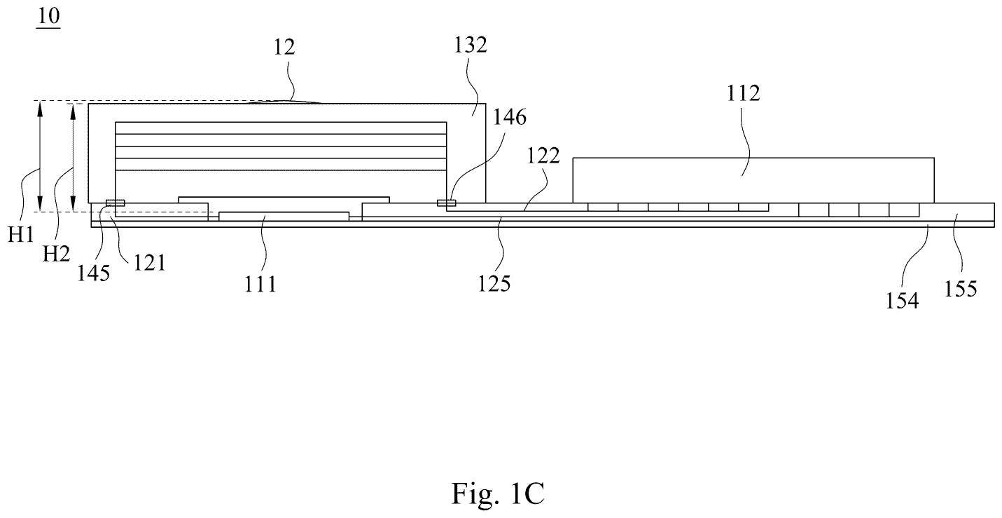

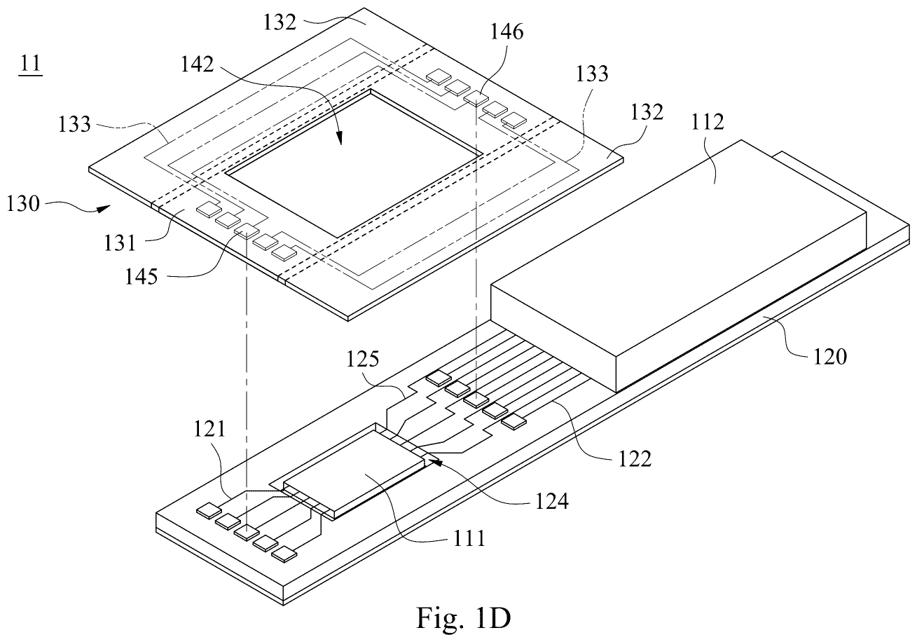

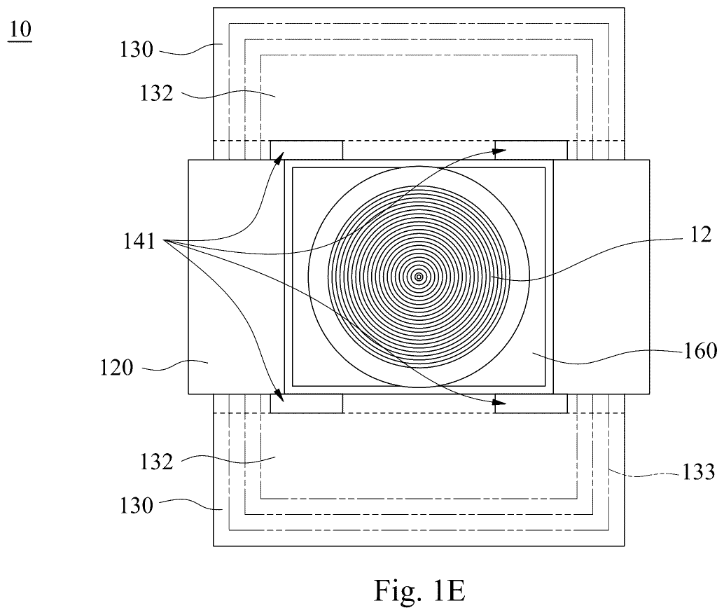

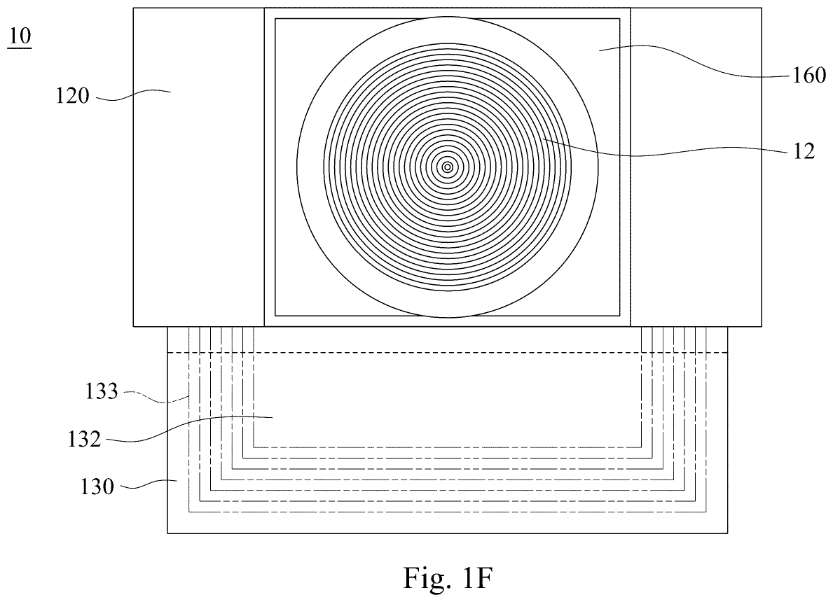

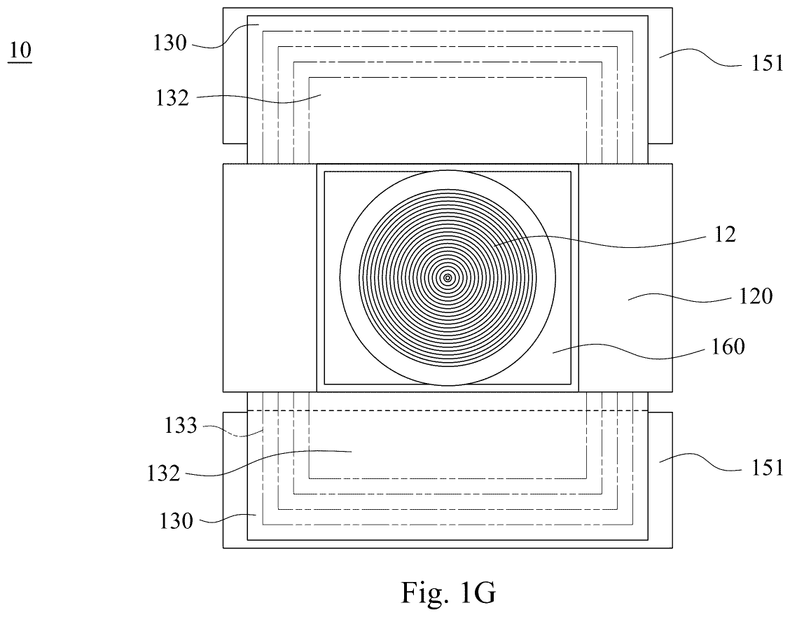

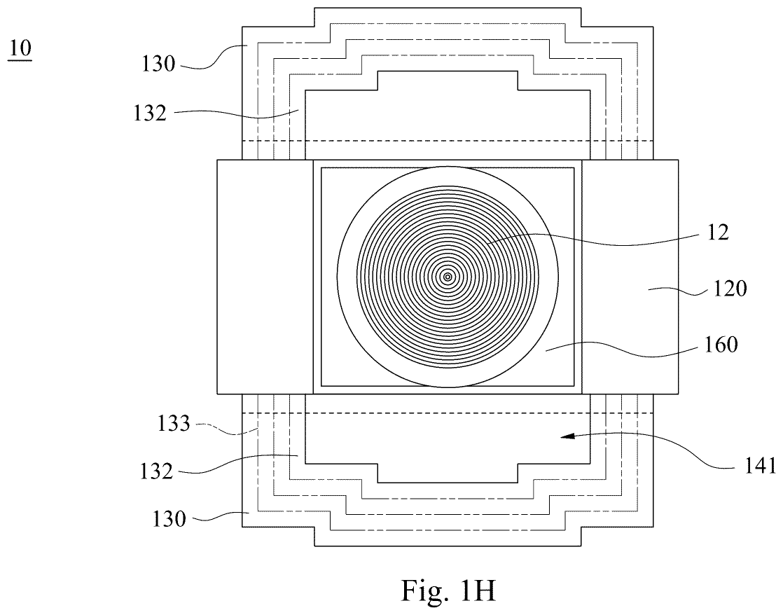

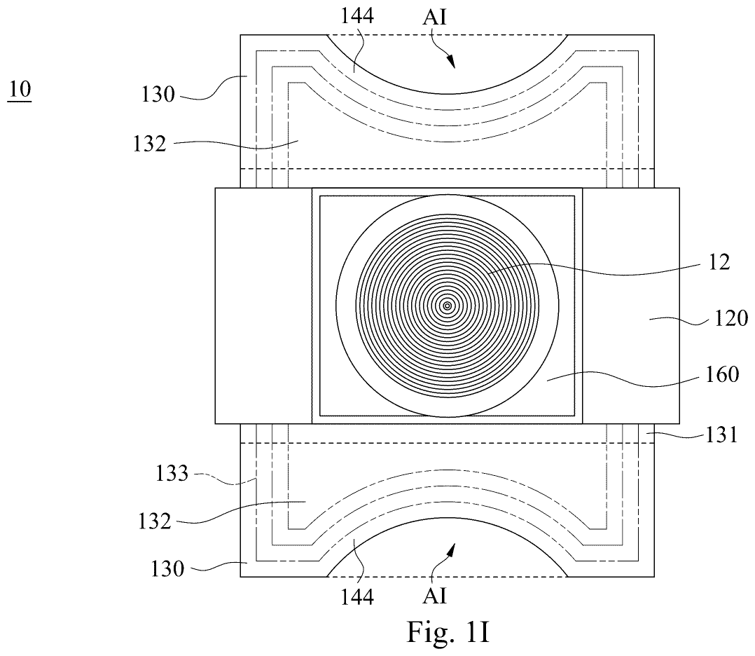

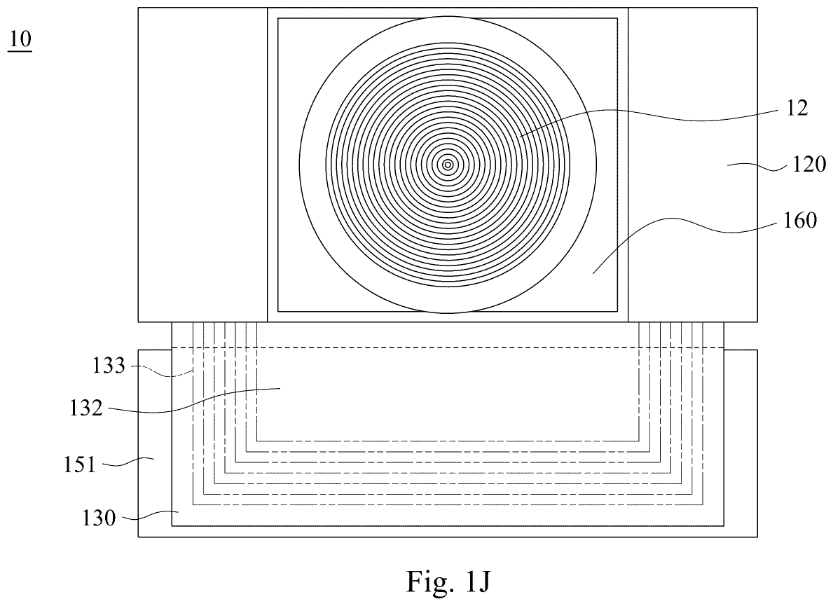

FIG. 1A is a three-dimensional view of a camera module 10 according to the 1st embodiment of the present disclosure. FIG. 1B is an exploded view of the camera module 10 according to the 1st embodiment in FIG. 1A. FIG. 1C is a cross-sectional view of the camera module 10 according to the 1st embodiment in FIG. 1A. FIG. 1D is an exploded view of the image sensor module 11 according to the 1st embodiment in FIG. 1A. In FIGS. 1A to 1D, the camera module 10 includes an image sensor module 11 and an imaging lens assembly 12, wherein the imaging lens assembly 12 is relatively disposed to the image sensor module 11. In detail, the camera module 10 can further have the functions as focus, zoom, image stabilization, and the aforementioned driving functions can be obtained via the holder of the imaging lens assembly, the imaging lens assembly or the cooperation with each other, but the present disclosure is not limited thereto.

The image sensor module 11 includes an electronic element assembly (its reference numeral is omitted), and the electronic element assembly includes a first electronic element 111, a second electronic element 112, an electronic element board 120 and a flexible circuit 130, wherein the first electronic element 111 and the second electronic element 112 are disposed at interval, the first electronic element 111 and the second electronic element 112 are disposed on the electronic element board 120, and the flexible circuit 130 is disposed on the electronic element board 120. In detail, the first electronic element 111 can be an image sensor, and the second electronic element 112 can be an image processing element.

The electronic element board 120 includes a first circuit 121 and a second circuit 122, wherein the first circuit 121 and the second circuit 122 are disposed on relative sides of the first electronic element 111, respectively, and the first circuit 121 is electronically connected to the first electronic element 111.

The flexible circuit 130 includes a connecting portion 131, a bending portion 132 and an electronic path 133. The connecting portion 131 is connected to the electronic element board 120. The bending portion 132 is disposed on a side of the connecting portion 131 away from the first electronic element 111 and the second electronic element 112, and the bending portion 132 bends along a thickness direction of the electronic element board 120. The electronic path 133 includes a first end 145 and a second end 146, and at least one portion of the electronic path 133 is disposed on the bending portion 132.

The first end 145 is electronically connected to the first circuit 121 and the first electronic element 111, the second end 146 is electronically connected to the second circuit 122 and the second electronic element 112, and the first end 145 and the second end 146 are disposed on the connecting portion 131.

In particular, the electronic element board 120 is configured to support the first electronic element 111 and the second electronic element 112, and at least one function of the mechanical strength support, the circuit disposition, the anti-electromagnetic interference or the grounding can be further obtained, wherein the electronic element board 120 can be the printed electronic element board or the ceramic electronic element board, and the electronic element board 120 can be further integrated with the flexible circuit 130 by the injection molding, but the present disclosure is not limited thereto.

By bending the bypass design of the flexible circuit 130, the degree of freedom of the wiring of the electronic element board 120 can be promoted, so that the volume of the electronic element assembly can be reduced. Further, the circuit can be away from the electronic elements (that is, the first electronic element 111 and the second electronic element 112) via the flexible circuit 130, so that the magnetic effect of the electric current, which is caused via the circuit, can be avoided influencing the electronic elements. Therefore, the volume is minimized while maintaining the working status of the electronic elements, and the design of the electronic element board 120 can be simplified via the flexible circuit 130 so as to shorten the design period and promote the manufacturing efficiency.

Moreover, the flexible circuit 130 can be obtained via the flexible printed circuit (FPC) or the multilayer circuit board, but the present disclosure is not limited thereto. Furthermore, the flexible circuit 130 extends from the electronic element board 120 and back to the electronic element board 120 so as to achieve the design of the electronic path 133.

The bending portion 132 and the electronic element board 120 can be fixed. Therefore, the signal interference, which is caused by shake, can be avoided by fixing the bending portion 132.

In FIG. 1A, a dimension of the bending portion 132 on the thickness direction of the electronic element board 120 can be less than or equal to a dimension of the bending portion 132 vertical to the thickness direction of the electronic element board 120 and vertical to a thickness direction of the bending portion 132. Therefore, the mechanical strength of the bending portion 132 after bending can be ensured.

The image sensor module 11 can further include a holder 160, wherein the holder 160 includes a through hole 161, the through hole 161 is correspondingly disposed to the first electronic element 111, and the bending portion 132 is disposed on the holder 160.

In FIG. 1C, an imaging lens assembly height H1 of the imaging lens assembly 12 is defined from the first electronic element 111 towards the thickness direction of the electronic element board 120, and a bending portion height H2 of the bending portion 132 of the flexible circuit 130 is defined from the first electronic element 111 towards the thickness direction of the electronic element board 120, wherein the imaging lens assembly height H1 can be larger than or equal to the bending portion height H2.

In FIG. 1A, the electronic element assembly can further include a shape maintaining element 152 correspondingly disposed to a side of the bending portion 132 connected to the connecting portion 131, and the shape maintaining element 152 and the electronic element board 120 are fixed. Therefore, the damage, which is caused by the collision during assembling, can be avoided, so that the assembling process can be improved.

In FIGS. 1B to 1D, the electronic element board 120 can further include an element corresponding hole 124, a substrate 154 and a circuit layer 155, wherein the first electronic element 111 is disposed on the element corresponding hole 124 and the substrate 154, and the first electronic element 111 is electronically connected to the circuit layer 155. Therefore, the height difference between the first electronic element 111 and the electronic element board 120 can be lowered so as to avoid the interference between the flexible circuit 130 and the gold wire on the first electronic element 111.

The electronic element board 120 can further include a third circuit 125, wherein the second electronic element 112 can be electronically connected to the second circuit 122, and the third circuit 125 is electronically connected to the first electronic element 111 and the second electronic element 112. In particular, the first electronic element 111 is connected to the second electronic element 112 via a plurality of intercommunication methods, so that the concentrated load can be avoided to reduce the entire dimension.

In FIGS. 1B and 1D, the connecting portion 131 of the flexible circuit 130 can include a window 142 relatively disposed to the first electronic element 111. Therefore, the first electronic element 111 can be avoided being blocked via the flexible circuit 130, so that the first electronic element 111 can have the functions as the photosensitivity and the heat dissipation.

The bending portion 132 does not include other electronic element. In particular, the aforementioned electronic element can include a passive element, a sensing element, a coil, and so on, so that the signal interference can be avoided.

FIG. 1E is a top view of the camera module 10 according to the 1st example of the 1st embodiment in FIG. 1A. In FIG. 1E, the flexible circuit 130 is disposed on double sides of the imaging lens assembly 12, and the bending portion 132 of the flexible circuit 130 can include a bending auxiliary hole 141, wherein the bending auxiliary hole 141 is disposed on a side of the bending portion 132 close to the electronic element board 120, and the electronic path 133 surrounds the bending auxiliary hole 141. According to the 1st example of the 1st embodiment, a number of the bending auxiliary hole 141 is four, but the present disclosure is not limited thereto.

FIG. 1F is a top view of the camera module 10 according to the 2nd example of the 1st embodiment in FIG. 1A. In FIG. 1F, the flexible circuit 130 is disposed on a single side of the imaging lens assembly 12.

FIG. 1G is a top view of the camera module 10 according to the 3rd example of the 1st embodiment in FIG. 1A. In FIG. 1G, the flexible circuit 130 is disposed on double sides of the imaging lens assembly 12, the electronic element assembly can further include a hardness reinforcing board 151 disposed on the bending portion 132, and the hardness reinforcing board 151 is fixed to the electronic element board 120, the holder 160 and the imaging lens assembly 12.

Therefore, the rigidity of the bending portion 132 can be enhanced via the hardness reinforcing board 151 so as to avoid the damage. Moreover, the hardness reinforcing board 151 can be a metal element so as to shield the electromagnetic interference (EMI), and the hardness reinforcing board 151 can be further combined with the bending portion 132 to form a composite board.

FIG. 1H is a top view of the camera module 10 according to the 4th example of the 1st embodiment in FIG. 1A. In FIG. 1H, the flexible circuit 130 is disposed on double sides of the imaging lens assembly 12, and the flexible circuit 130 is irregular, wherein the bending portion 132 of the flexible circuit 130 can include a bending auxiliary hole 141 disposed on a side of the bending portion 132 close to the electronic element board 120, and the electronic path 133 surrounds the bending auxiliary hole 141.

FIG. 1I is a top view of the camera module 10 according to the 5th example of the 1st embodiment in FIG. 1A. In FIG. 1I, the flexible circuit 130 is disposed on double sides of the imaging lens assembly 12, the bending portion 132 of the flexible circuit 130 is opaque, and the bending portion 132 can include a blocking area 144, wherein the blocking area 144 is disposed on a side of the bending portion 132 away from the connecting portion 131, and the blocking area 144 is correspondingly disposed to an image height of the imaging lens assembly 12. Therefore, the non-imaging light can be blocked to enter the imaging lens assembly 12 to form the glare so as to enhance the optical quality.

In particular, the non-imaging light can be blocked by the flexible circuit 130 via the blocking area 144, and the area interfered with the imaging lens assembly 12 can be avoided, that is an avoid-interference area Al in FIG. 1I.

FIG. 1J is a top view of the camera module 10 according to the 6th example of the 1st embodiment in FIG. 1A. In FIG. 1J, the flexible circuit 130 is disposed on a single side of the imaging lens assembly 12, the electronic element assembly can further include a hardness reinforcing board 151 disposed on the bending portion 132, and the hardness reinforcing board 151 is fixed to the electronic element board 120, the holder 160 and the imaging lens assembly 12.

### 2nd Embodiment

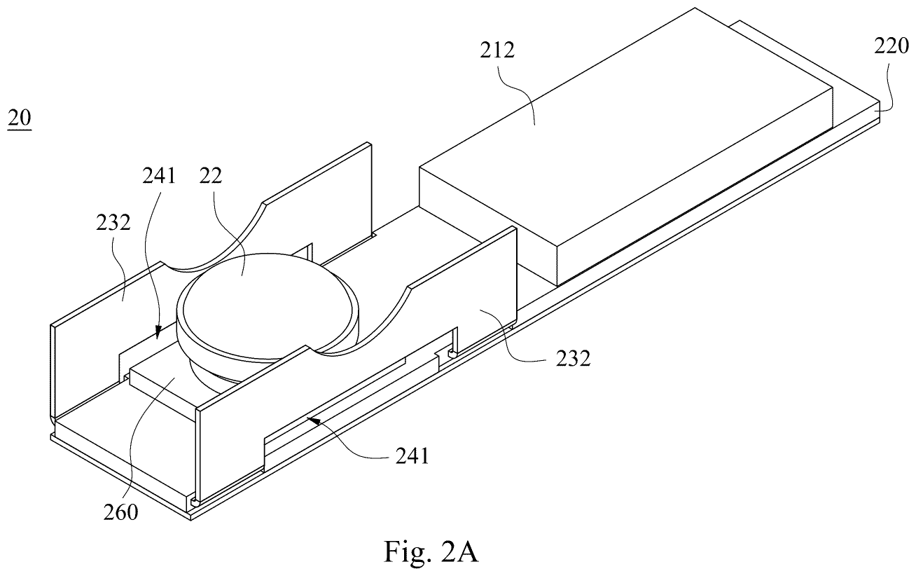

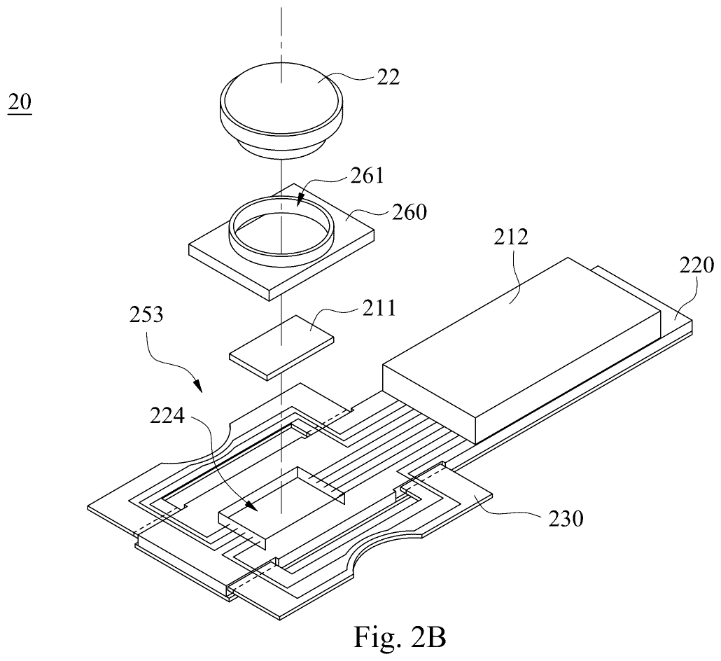

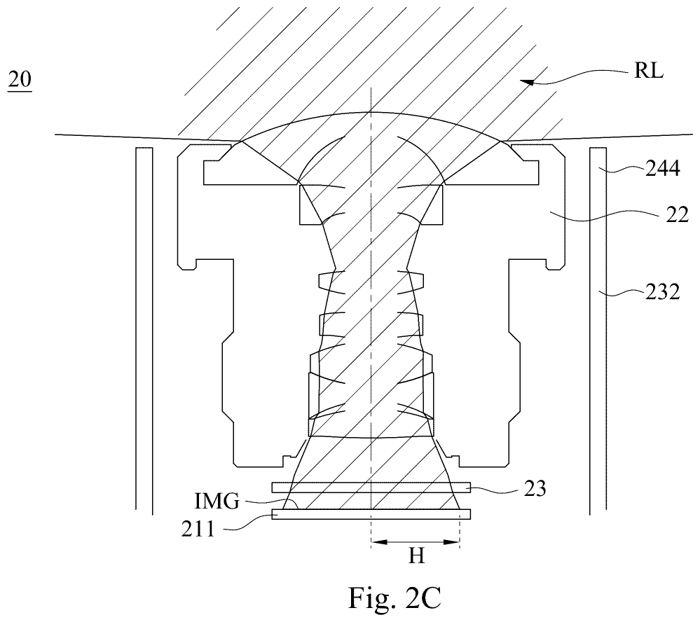

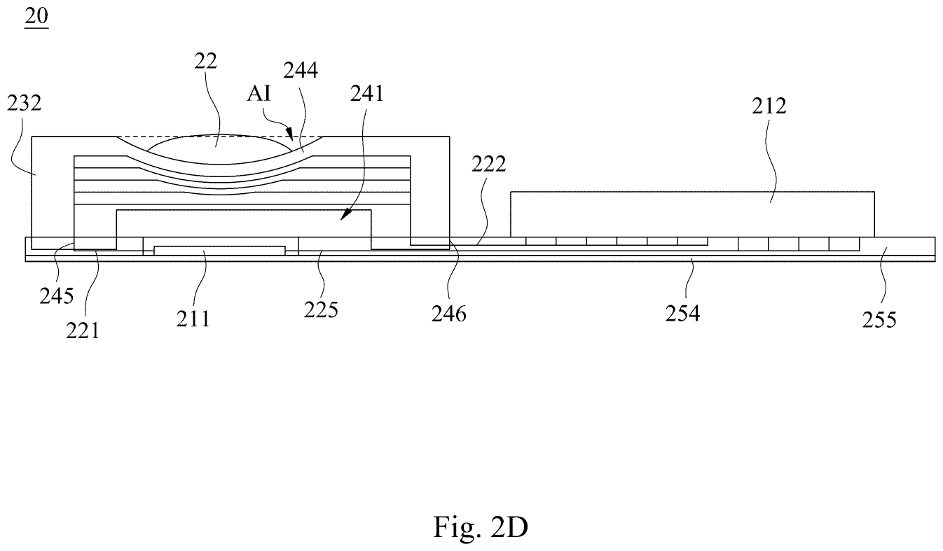

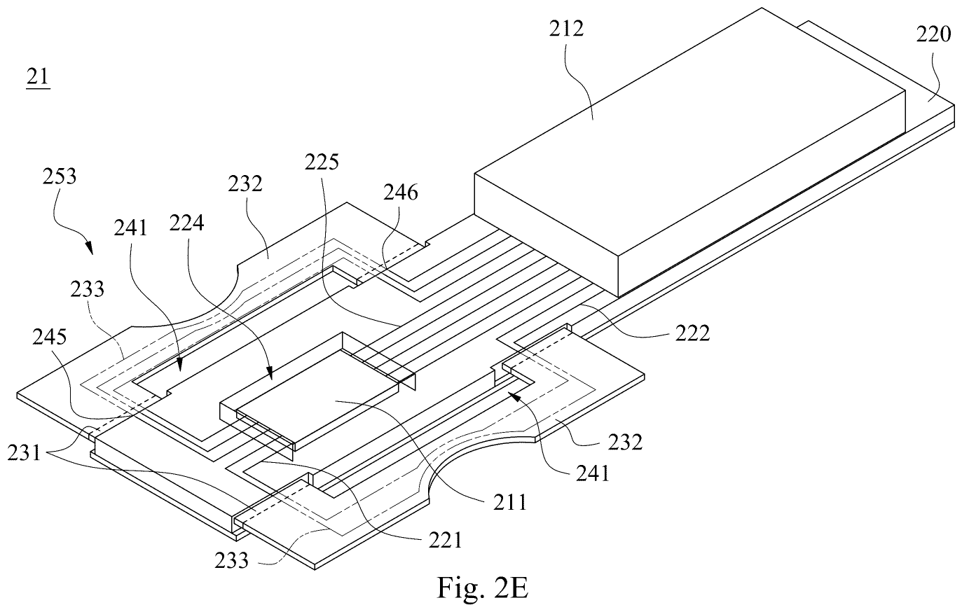

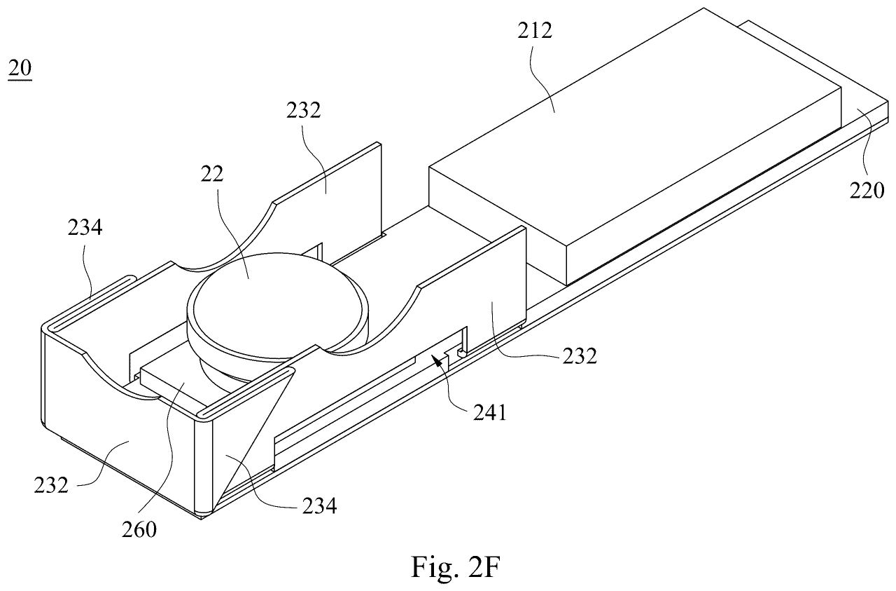

FIG. 2A is a three-dimensional view of a camera module 20 according to the 2nd embodiment of the present disclosure. FIG. 2B is an exploded view of the camera module 20 according to the 2nd embodiment in FIG. 2A. FIG. 2C is a schematic view of a range RL of an imaging light path of the camera module 20 according to the 2nd embodiment in FIG. 2A. In FIGS. 2A to 2C, the camera module 20 includes an image sensor module 21 (labeled in FIG. 2E) and an imaging lens assembly 22, wherein the imaging lens assembly 22 is relatively disposed to the image sensor module 21.

The image sensor module 21 includes an electronic element assembly (its reference numeral is omitted), and the electronic element assembly includes a first electronic element 211, a second electronic element 212, an electronic element board 220 and a flexible circuit 230, wherein the first electronic element 211 and the second electronic element 212 are disposed at interval, the first electronic element 211 and the second electronic element 212 are disposed on the electronic element board 220, and the flexible circuit 230 is disposed on the electronic element board 220. In detail, the first electronic element 211 can be an image sensor, and the second electronic element 212 can be an image processing element.

In FIG. 2C, the camera module 20 can further include a filter element 23, wherein the imaging light passes through the filter element 23 and then images on a sensing surface IMG of the first electronic element 211.

FIG. 2D is a cross-sectional view of the camera module 20 according to the 1st example of the 2nd embodiment in FIG. 2A. FIG. 2E is a schematic view of the image sensor module 21 according to the 1st example of the 2nd embodiment in FIG. 2A. In FIGS. 2D and 2E, the electronic element board 220 includes a first circuit 221 and a second circuit 222, wherein the first circuit 221 and the second circuit 222 are disposed on relative sides of the first electronic element 211, respectively, and the first circuit 221 is electronically connected to the first electronic element 211.

In FIGS. 2C to 2E, the flexible circuit 230 includes a connecting portion 231, a bending portion 232 and an electronic path 233. The connecting portion 231 is connected to the electronic element board 220. The bending portion 232 is disposed on a side of the connecting portion 231 away from the first electronic element 211 and the second electronic element 212, and the bending portion 232 bends along a thickness direction of the electronic element board 220. The electronic path 233 includes a first end 245 and a second end 246, and at least one portion of the electronic path 233 is disposed on the bending portion 232.

The first end 245 is electronically connected to the first circuit 221 and the first electronic element 211, the second end 246 is electronically connected to the second circuit 222 and the second electronic element 212, and the first end 245 and the second end 246 are disposed on the connecting portion 231.

In FIGS. 2A and 2B, the image sensor module 21 can further include a holder 260, wherein the holder 260 includes a through hole 261, the through hole 261 is correspondingly disposed to the first electronic element 211, and the bending portion 232 is disposed on the holder 260. Moreover, the holder 260 can be an imaging lens base.

In FIGS. 2B and 2D, the electronic element board 220 can further include an element corresponding hole 224, a substrate 254 and a circuit layer 255, wherein the first electronic element 211 is disposed on the element corresponding hole 224 and the substrate 254, and the first electronic element 211 is electronically connected to the circuit layer 255.

In FIGS. 2D and 2E, the electronic element board 220 can further include a third circuit 225, wherein the second electronic element 212 can be electronically connected to the second circuit 222, and the third circuit 225 is electronically connected to the first electronic element 211 and the second electronic element 212.

In FIGS. 2A, 2D and 2E, the bending portion 232 of the flexible circuit 230 can include a bending auxiliary hole 241, wherein the bending auxiliary hole 241 is disposed on a side of the bending portion 232 close to the electronic element board 220, and the electronic path 233 surrounds the bending auxiliary hole 241. Further, a dimension of the bending auxiliary hole 241 on the thickness direction of the electronic element board 220 can be less than or equal to a dimension of the bending auxiliary hole 241 vertical to the thickness direction of the electronic element board 220 and vertical to a thickness direction of the bending portion 232. Therefore, the unpredictable deformation of the electronic path 233 during bending can be avoided so as to protect the electronic path 233.

In FIGS. 2B and 2E, the electronic element assembly can further include a multilayer circuit board 253, wherein the multilayer circuit board 253 can include the electronic element board 220 and the flexible circuit 230, and the flexible circuit 230 extends from the electronic element board 220 towards a direction away from the first electronic element 211.

In FIGS. 2C and 2D, the bending portion 232 of the flexible circuit 230 is opaque, and the bending portion 232 can include a blocking area 244, wherein the blocking area 244 is disposed on a side of the bending portion 232 away from the connecting portion 231, and the blocking area 244 is correspondingly disposed to an image height H of the imaging lens assembly 22.

In particular, the non-imaging light can be blocked by the flexible circuit 230 via the blocking area 244 to form the range RL of the imaging light path as shown in FIG. 2C, and the area interfered with the imaging lens assembly 22 can be avoided, that is an avoid-interference area Al in FIG. 2D.

FIG. 2F is a three-dimensional view of the camera module 20 according to the 2nd example of the 2nd embodiment in FIG. 2A. In FIG. 2F, the flexible circuit 230 can further include a plurality of vice bending portions 234, wherein the vice bending portions 234 are further disposed on the bending portion 232, and the vice bending portions 234 can be further configured to fix the bending portion 232.

### 3rd Embodiment

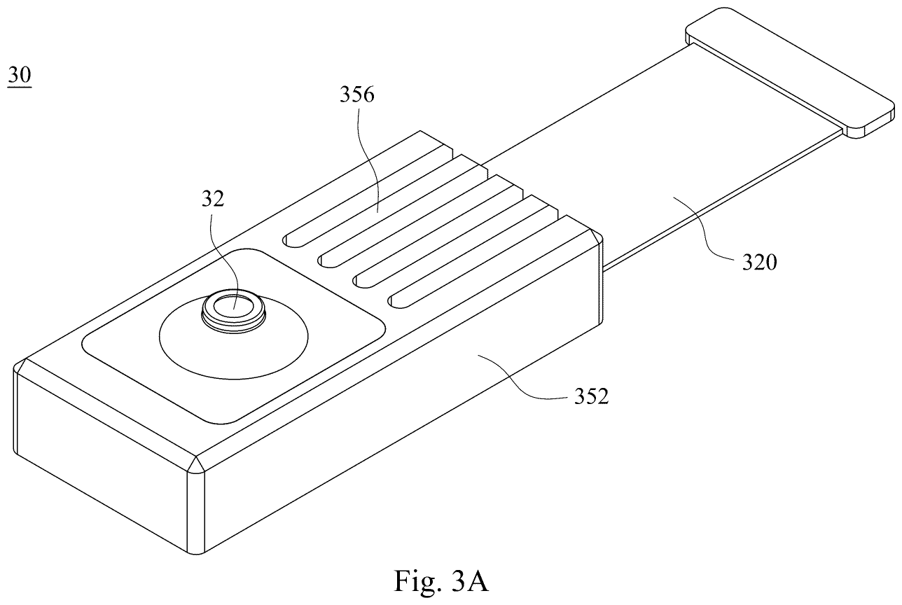

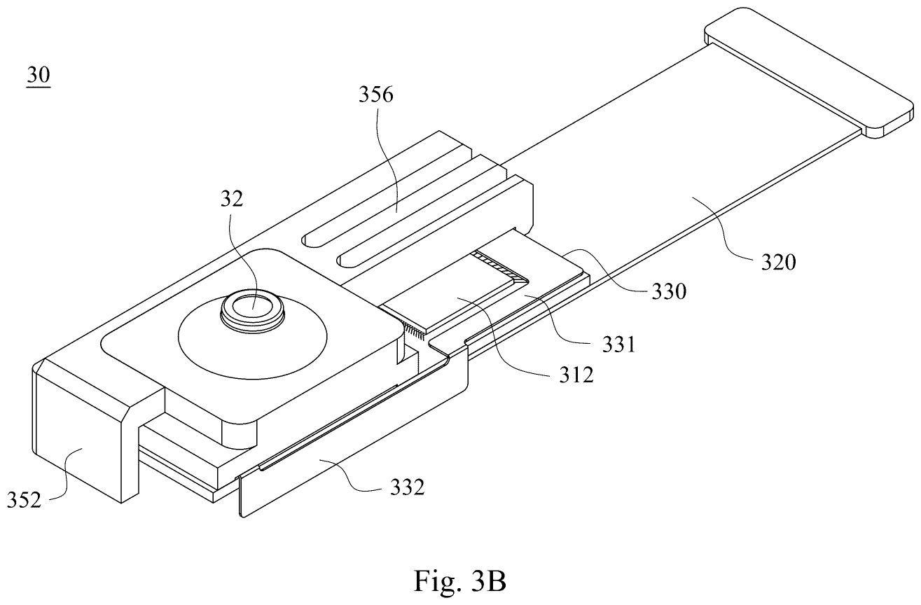

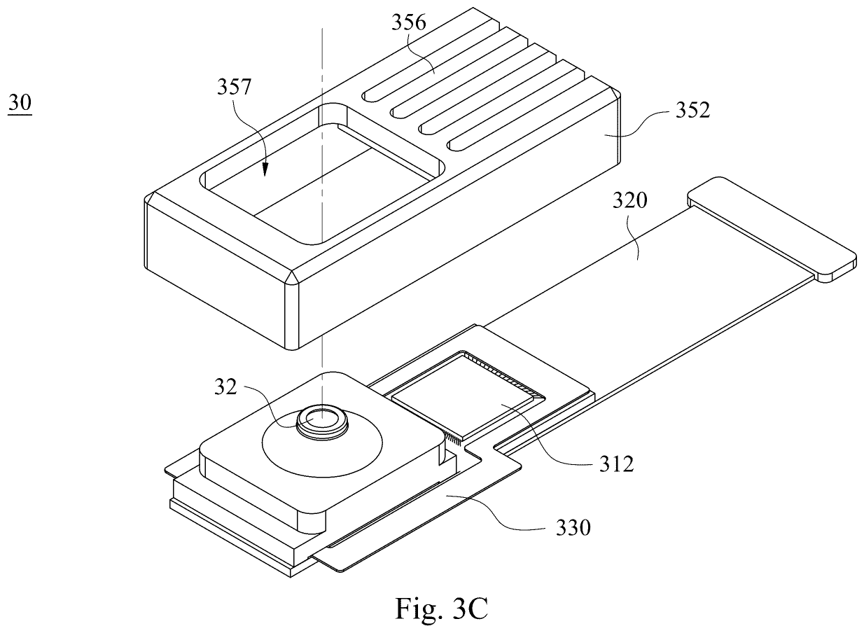

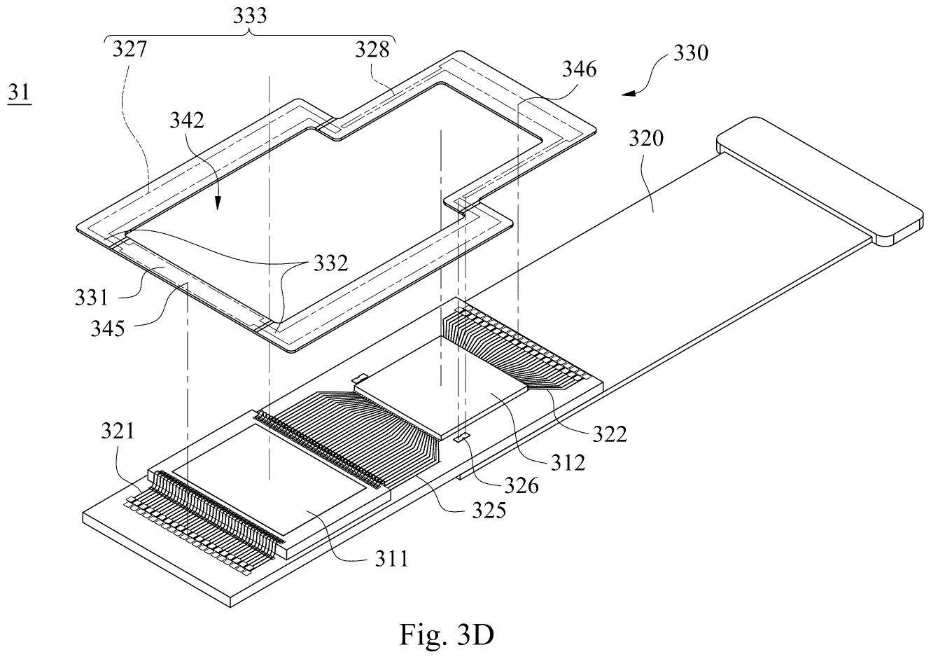

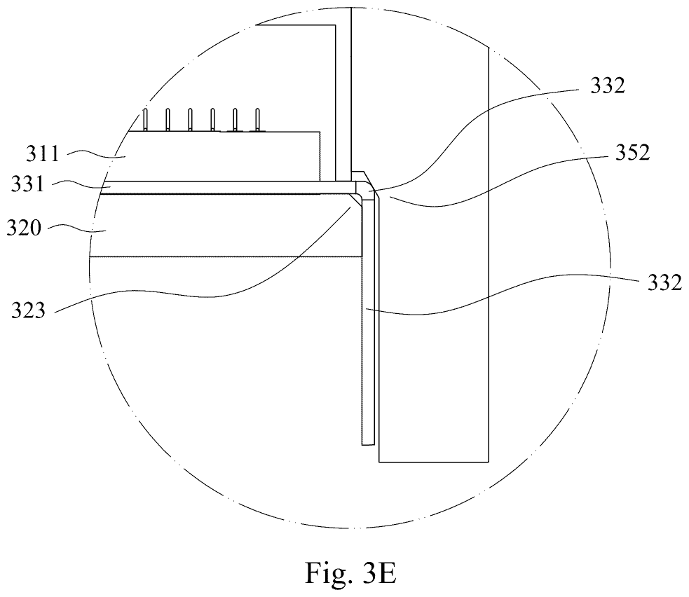

FIG. 3A is a three-dimensional view of a camera module 30 according to the 3rd embodiment of the present disclosure. FIG. 3B is a partial cross-sectional view of the camera module 30 according to the 3rd embodiment in FIG. 3A. FIG. 3C is an exploded view of the camera module 30 according to the 3rd embodiment in FIG. 3A. In FIGS. 3A to 3C, the camera module 30 includes an image sensor module 31 (labeled in FIG. 3D) and an imaging lens assembly 32, wherein the imaging lens assembly 32 is relatively disposed to the image sensor module 31.

FIG. 3D is an exploded view of the image sensor module 31 according to the 3rd embodiment in FIG. 3A. In FIGS. 3B to 3D, the image sensor module 31 includes an electronic element assembly (its reference numeral is omitted), and the electronic element assembly includes a first electronic element 311, a second electronic element 312, an electronic element board 320 and a flexible circuit 330, wherein the first electronic element 311 and the second electronic element 312 are disposed at interval, the first electronic element 311 and the second electronic element 312 are disposed on the electronic element board 320, and the flexible circuit 330 is disposed on the electronic element board 320. In detail, the first electronic element 311 can be an image sensor, and the second electronic element 312 can be an image processing element.

In FIG. 3D, the electronic element board 320 includes a first circuit 321 and a second circuit 322, wherein the first circuit 321 and the second circuit 322 are disposed on relative sides of the first electronic element 311, respectively, and the first circuit 321 is electronically connected to the first electronic element 311.

FIG. 3E is a partial enlarged view of the camera module 30 according to the 3rd embodiment in FIG. 3A. In FIGS. 3B, 3D and 3E, the flexible circuit 330 includes a connecting portion 331, a bending portion 332 and an electronic path 333. The connecting portion 331 is connected to the electronic element board 320. The bending portion 332 is disposed on a side of the connecting portion 331 away from the first electronic element 311 and the second electronic element 312, and the bending portion 332 bends along a thickness direction of the electronic element board 320. The electronic path 333 includes a first end 345 and a second end 346, and at least one portion of the electronic path 333 is disposed on the bending portion 332.

The first end 345 is electronically connected to the first circuit 321 and the first electronic element 311, the second end 346 is electronically connected to the second circuit 322 and the second electronic element 312, and the first end 345 and the second end 346 are disposed on the connecting portion 331.

In FIGS. 3A to 3C and 3E, the electronic element assembly can further include a shape maintaining element 352 correspondingly disposed to a side of the bending portion 332 connected to the connecting portion 331, and the shape maintaining element 352 and the electronic element board 320 are fixed.

In detail, the shape maintaining element 352 can be a holder, and the shape maintaining element 352 can include a cooling structure 356 and a through hole 357, wherein the cooling structure 356 is corresponding to the second electronic element 312, and the through hole 357 is corresponding to the imaging lens assembly 32.

In FIG. 3D, the electronic element board 320 can further include a third circuit 325, wherein the second electronic element 312 can be electronically connected to the second circuit 322, and the third circuit 325 is electronically connected to the first electronic element 311 and the second electronic element 312.

The connecting portion 331 of the flexible circuit 330 can include a window 342 relatively disposed to the first electronic element 311 and the second electronic element 312.

In FIG. 3E, the electronic element board 320 can further include a bend guiding structure 323 correspondingly disposed to a side of the bending portion 332 connected to the connecting portion 331, and the bending portion 332 bends along the bend guiding structure 323. Therefore, the degree of emerging of the bending portion 332 from the surface can be reduced so as to enhance the assembling quality.

In FIG. 3D, the electronic element board 320 can further include a contacting point 326, and the electronic path 333 can include a first sub-path 327 and a second sub-path 328, wherein the first sub-path 327 is electronically connected to the first circuit 321, the second sub-path 328 is electronically connected to the second circuit 322, and the first sub-path 327 and the second sub-path 328 are electronically connected via the contacting point 326. Therefore, the stability of the flexible circuit 330 can be further enhanced. In particular, each of the first sub-path 327 and the second sub-path 328 can be a gold wire, so that the wiring process can be finished at once.

### 4th Embodiment

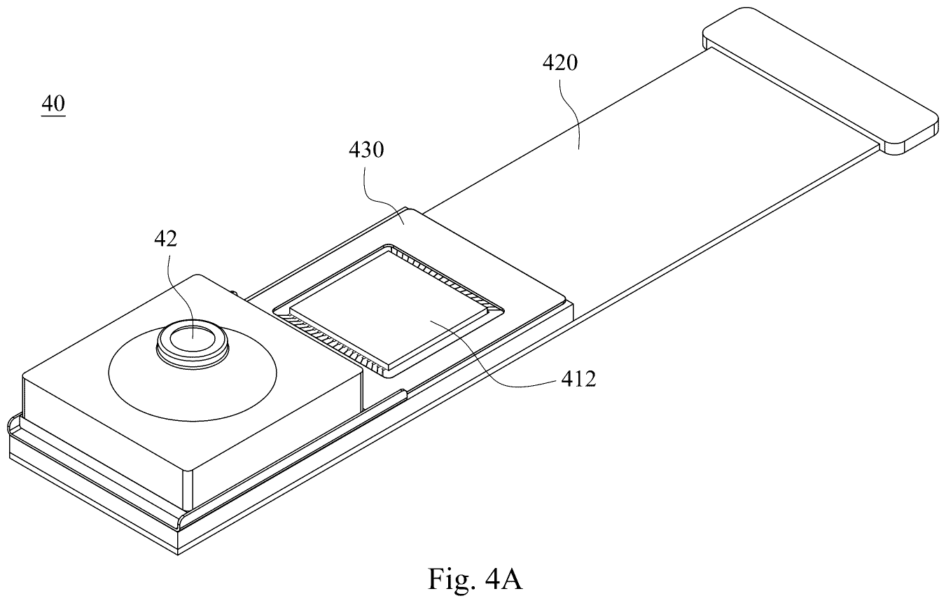

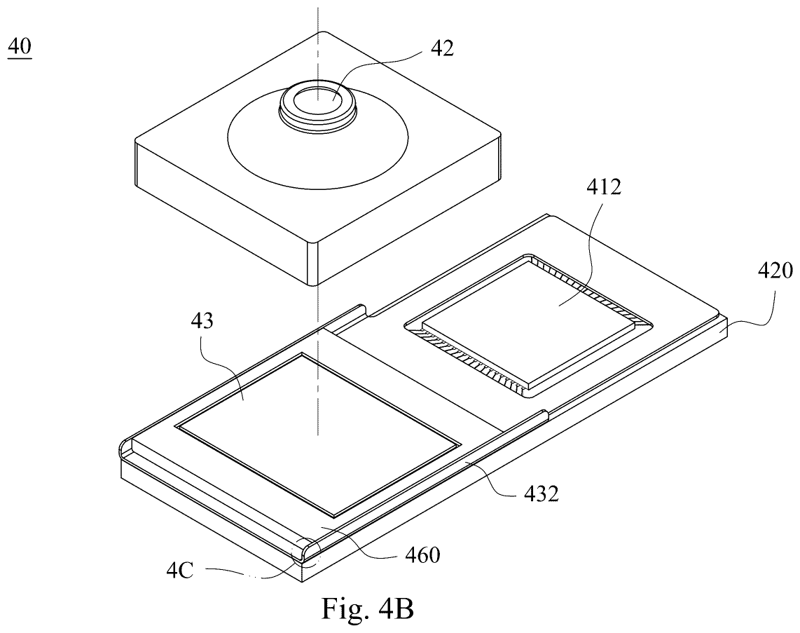

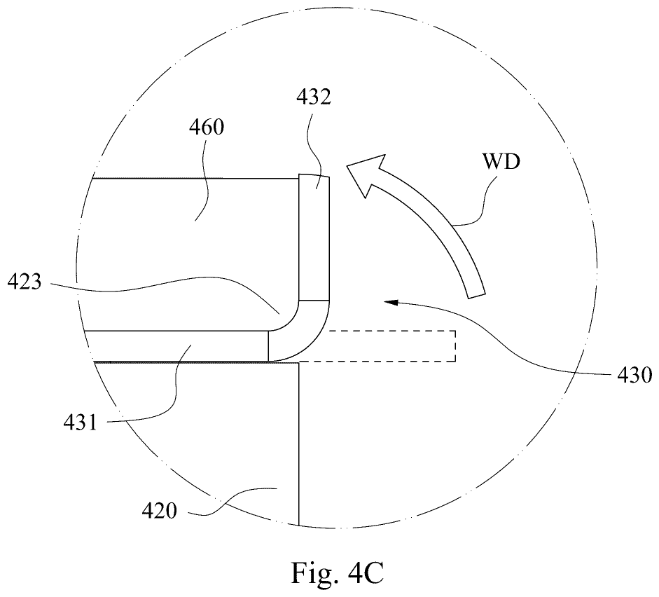

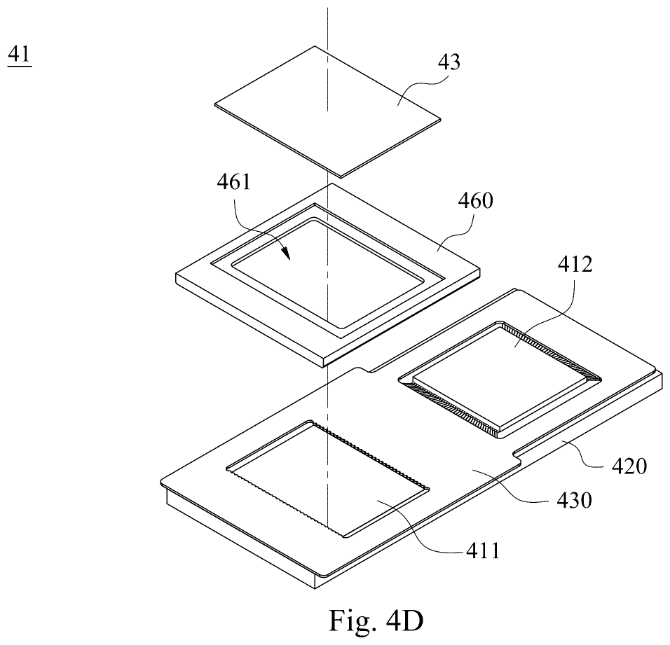

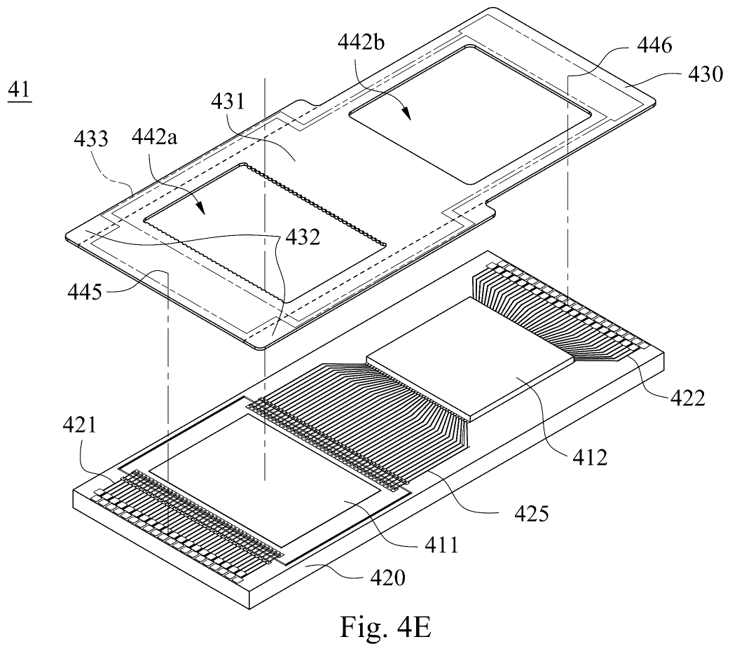

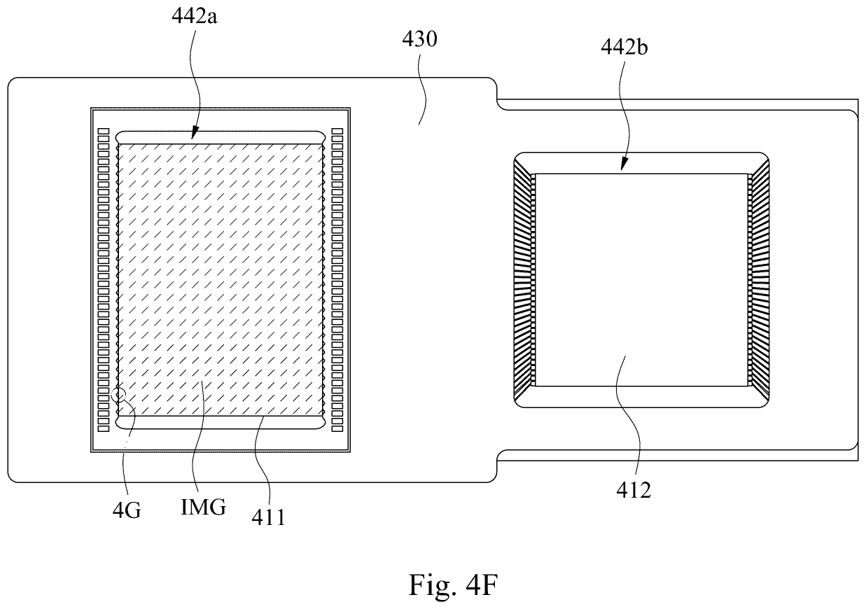

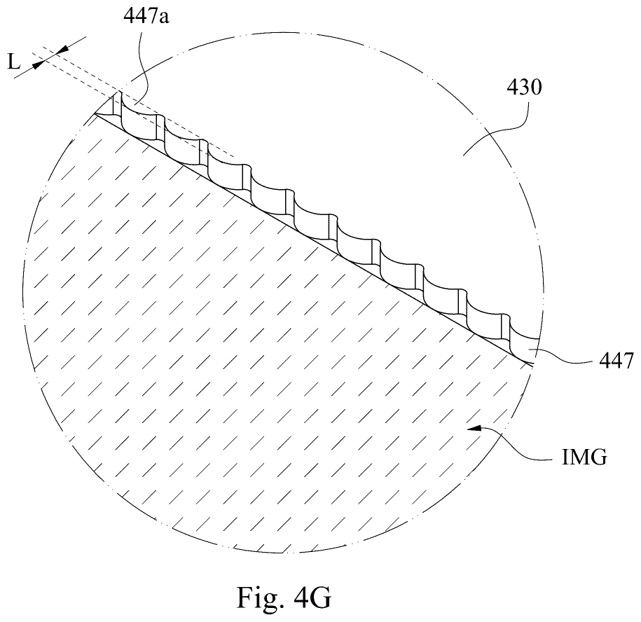

FIG. 4A is a three-dimensional view of a camera module 40 according to the 4th embodiment of the present disclosure. FIG. 4B is an exploded view of the camera module 40 according to the 4th embodiment in FIG. 4A. In FIGS. 4A and 4B, the camera module 40 includes an image sensor module 41 (labeled in FIG. 4D) and an imaging lens assembly 42, wherein the imaging lens assembly 42 is relatively disposed to the image sensor module 41.

FIG. 4C is a partial enlarged view of the camera module 40 according to the 4th embodiment in FIG. 4B. FIG. 4D is an exploded view of the image sensor module 41 according to the 4th embodiment in FIG. 4A. FIG. 4E is a partial exploded view of the image sensor module 41 according to the 4th embodiment in FIG. 4A. In FIGS. 4A to 4E, the image sensor module 41 includes an electronic element assembly (its reference numeral is omitted), and the electronic element assembly includes a first electronic element 411, a second electronic element 412, an electronic element board 420 and a flexible circuit 430, wherein the first electronic element 411 and the second electronic element 412 are disposed at interval, the first electronic element 411 and the second electronic element 412 are disposed on the electronic element board 420, and the flexible circuit 430 is disposed on the electronic element board 420. In detail, the first electronic element 411 can be an image sensor, and the second electronic element 412 can be an image processing element.

In FIGS. 4B and 4D, the camera module 40 can further include a filter element 43, wherein the filter element 43 is corresponding to the first electronic element 411.

In FIG. 4E, the electronic element board 420 includes a first circuit 421 and a second circuit 422, wherein the first circuit 421 and the second circuit 422 are disposed on relative sides of the first electronic element 411, respectively, and the first circuit 421 is electronically connected to the first electronic element 411.

In FIGS. 4B, 4C and 4E, the flexible circuit 430 includes a connecting portion 431, a bending portion 432 and an electronic path 433. The connecting portion 431 is connected to the electronic element board 420. The bending portion 432 is disposed on a side of the connecting portion 431 away from the first electronic element 411 and the second electronic element 412, and the bending portion 432 bends along a thickness direction of the electronic element board 420. The electronic path 433 includes a first end 445 and a second end 446, and at least one portion of the electronic path 433 is disposed on the bending portion 432.

The first end 445 is electronically connected to the first circuit 421 and the first electronic element 411, the second end 446 is electronically connected to the second circuit 422 and the second electronic element 412, and the first end 445 and the second end 446 are disposed on the connecting portion 431.

In FIGS. 4B to 4D, the image sensor module 41 can further include a holder 460, wherein the holder 460 includes a through hole 461, the through hole 461 is correspondingly disposed to the first electronic element 411 and the filter element 43, and the bending portion 432 is disposed on the holder 460.

In FIG. 4C, the holder 460 can further include a bend guiding structure 423 correspondingly disposed to a side of the bending portion 432 connected to the connecting portion 431, and the bending portion 432 bends along the bend guiding structure 423. Furthermore, the bending portion 432 bends along a bending direction WD.

FIG. 4F is a top view of the image sensor module 41 according to the 4th embodiment in FIG. 4A. FIG. 4G is a partial enlarged view of the image sensor module 41 according to the 4th embodiment in FIG. 4F. In FIGS. 4E to 4G, the connecting portion 431 of the flexible circuit 430 can include a plurality of windows, and the windows are a first window 442a and a second window 442b, wherein the first window 442a and the second window 442b are relatively disposed to a sensing surface IMG of the first electronic element 411.

The flexible circuit 430 is opaque, the first window 442a can include an anti-glare structure 447, and the anti-glare structure 447 can include a plurality of protrusions 447a, wherein the protrusions 447a are tapered towards a direction close to the sensing surface IMG, a length of each of the protrusions 447a along a direction close to the first electronic element 411 is L, and the length Lis 0.2 mm. Therefore, the glare caused by the contacting point of the circuit can be blocked via the flexible circuit 430, and the glare caused by reflecting from the first window 442a to the sensing surface IMG can be further avoided via the protrusions 447a. The protrusions 447a are tapered towards a direction parallel to the sensing surface IMG, the protrusions 447a can be further tapered on a direction vertical to the sensing surface IMG, and the protrusions 447a are continuously disposed along the first window 442a.

### 5th Embodiment

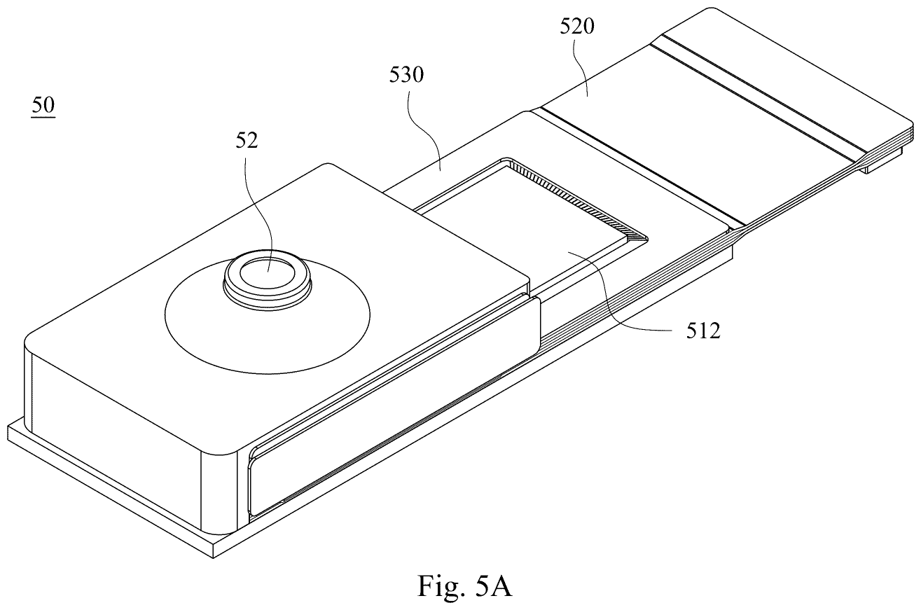

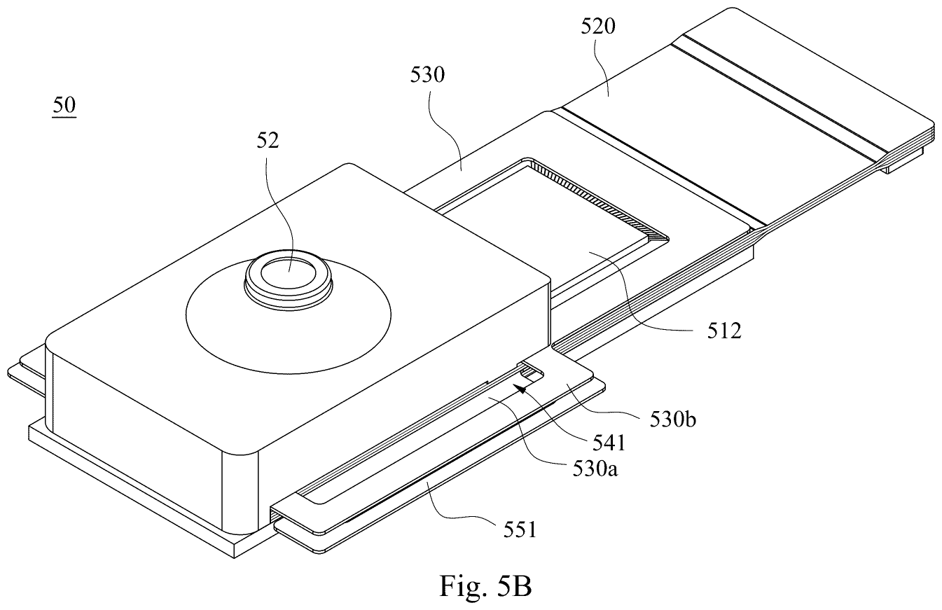

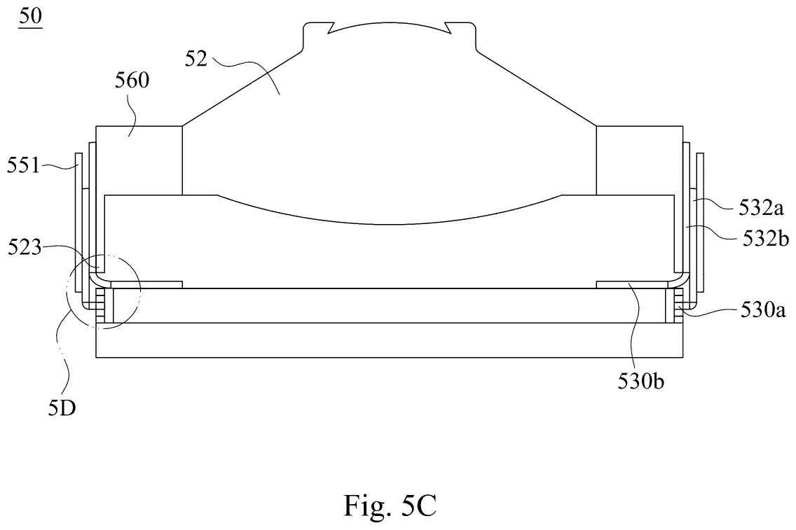

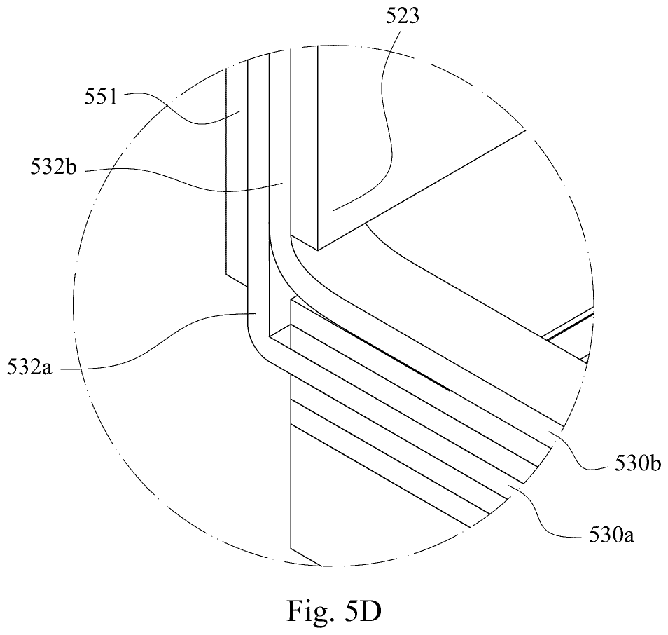

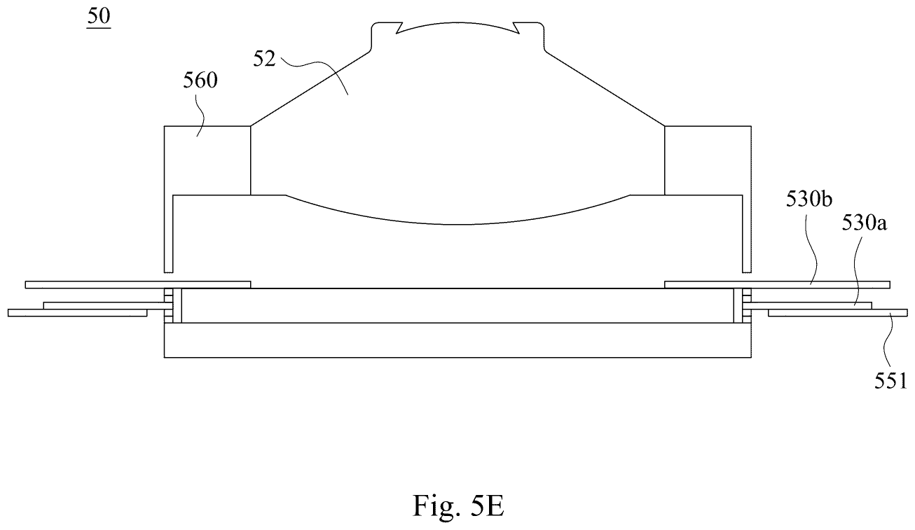

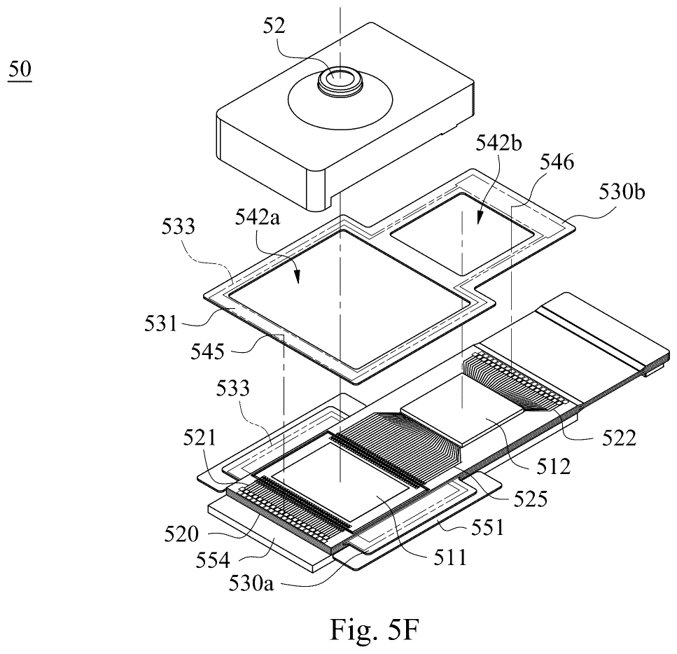

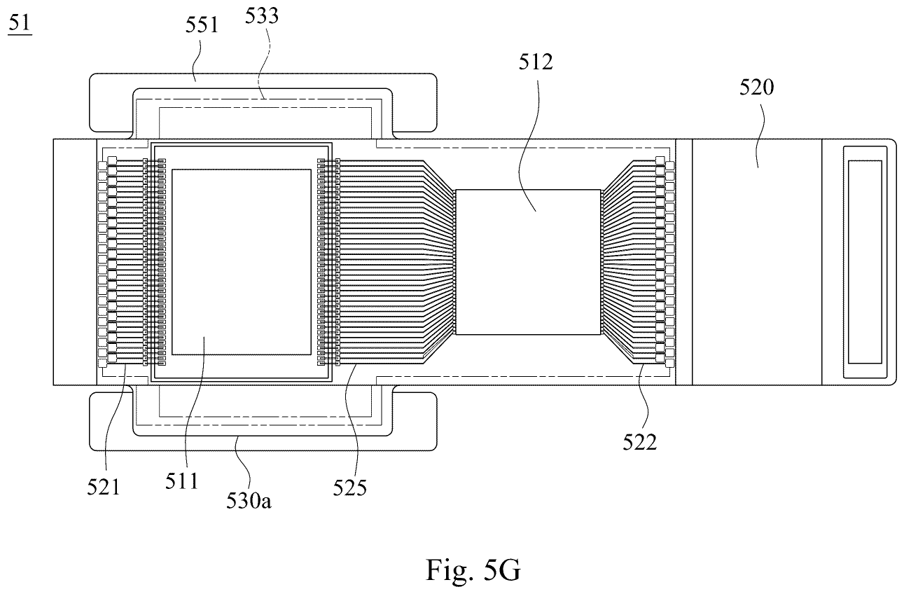

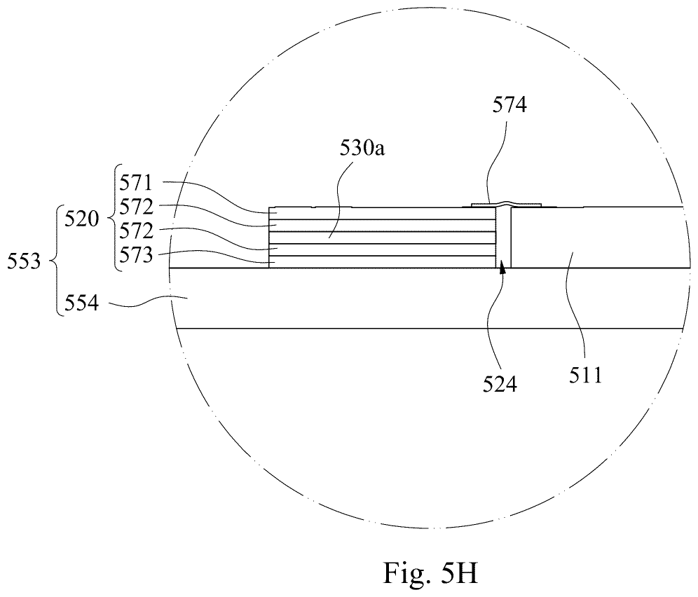

FIG. 5A is a three-dimensional view of a camera module 50 according to the 5th embodiment of the present disclosure. FIG. 5B is a schematic view of the camera module 50 according to the 5th embodiment in FIG. 5A. In FIGS. 5A and 5B, the camera module 50 includes an image sensor module 51 (labeled in FIG. 5G) and an imaging lens assembly 52, wherein the imaging lens assembly 52 is relatively disposed to the image sensor module 51.

FIG. 5C is a cross-sectional view of the camera module 50 according to the 5th embodiment in FIG. 5A. FIG. 5D is a partial enlarged view of the camera module 50 according to the 5th embodiment in FIG. 5C. FIG. 5E is another schematic view of the camera module 50 according to the 5th embodiment in FIG. 5A. FIG. 5F is an exploded view of the camera module 50 according to the 5th embodiment in FIG. 5A. FIG. 5G is a top view of the image sensor module 51 according to the 5th embodiment in FIG. 5A. In FIGS. 5A to 5G, the image sensor module 51 includes an electronic element assembly (its reference numeral is omitted), and the electronic element assembly includes a first electronic element 511, a second electronic element 512, an electronic element board 520 and flexible circuits, wherein the first electronic element 511 and the second electronic element 512 are disposed at interval, the first electronic element 511 and the second electronic element 512 are disposed on the electronic element board 520, and the flexible circuits are disposed on the electronic element board 520. In detail, the first electronic element 511 can be an image sensor, and the second electronic element 512 can be an image processing element.

In detail, the flexible circuits include a first flexible circuit 530a and a second flexible circuit 530b, and the first flexible circuit 530a and the second flexible circuit 530b are disposed on the electronic element board 520.

In FIGS. 5F and 5G, the electronic element board 520 includes a first circuit 521 and a second circuit 522, wherein the first circuit 521 and the second circuit 522 are disposed on relative sides of the first electronic element 511, respectively, and the first circuit 521 is electronically connected to the first electronic element 511.

In FIGS. 5C, 5D and 5F, each of the first flexible circuit 530a and the second flexible circuit 530b includes a connecting portion 531, a bending portion and an electronic path 533. The connecting portion 531 is connected to the electronic element board 520. The bending portion is disposed on a side of the connecting portion 531 away from the first electronic element 511 and the second electronic element 512, and the bending portion bends along a thickness direction of the electronic element board 520. The electronic path 533 includes a first end 545 and a second end 546, and at least one portion of the electronic path 533 is disposed on the bending portion.

Furthermore, the first flexible circuit 530a includes a first bending portion 532a, and the second flexible circuit 530b includes a second bending portion 532b.

The first end 545 is electronically connected to the first circuit 521 and the first electronic element 511, the second end 546 is electronically connected to the second circuit 522 and the second electronic element 512, and the first end 545 and the second end 546 are disposed on the connecting portion 531.

In FIGS. 5C and 5E, the image sensor module 51 can further include a holder 560, wherein the holder 560 includes a through hole (its reference numeral is omitted), the through hole is correspondingly disposed to the first electronic element 511, and the first bending portion 532a and the second bending portion 532b are disposed on the holder 560.

In FIGS. 5C and 5D, the imaging lens assembly 52 can further include a bend guiding structure 523 correspondingly disposed to a side of the first bending portion 532a connected to the connecting portion 531 and a side of the second bending portion 532b connected to the connecting portion 531, and the first bending portion 532a and the second bending portion 532b bend along the bend guiding structure 523.

In FIG. 5B, the second bending portion 532b of the second flexible circuit 530b can include a bending auxiliary hole 541, wherein the bending auxiliary hole 541 is disposed on a side of the second bending portion 532b close to the electronic element board 520, and the electronic path 533 surrounds the bending auxiliary hole 541.

In FIG. 5F, the connecting portion 531 of the second flexible circuit 530b can include a plurality of windows, and the windows are a first window 542a and a second window 542b, wherein the first window 542a is relatively disposed to a sensing surface of the first electronic element 511, and the second window 542b is relatively disposed to the second electronic element 512.

In FIGS. 5B to 5G, the electronic element assembly can further include a hardness reinforcing board 551 disposed on the first bending portion 532a, and the hardness reinforcing board 551 is fixed to the electronic element board 520, the holder 560 and the imaging lens assembly 52.

FIG. 5H is a partial enlarged view of the image sensor module 51 according to the 5th embodiment in FIG. 5A. In FIG. 5H, the electronic element assembly can further include a multilayer circuit board 553, wherein the multilayer circuit board 553 can include the electronic element board 520 and the first flexible circuit 530a, and the first flexible circuit 530a extends from the electronic element board 520 towards a direction away from the first electronic element 511.

In FIGS. 5F and 5H, the electronic element board 520 can further include an element corresponding hole 524, a substrate 554, an upper circuit 571, hard layers 572, a lower circuit 573 and a connecting wire 574, wherein the first electronic element 511 is disposed on the element corresponding hole 524 and the substrate 554, the first flexible circuit 530a is disposed between the hard layers 572, the hard layers 572 are disposed on the upper circuit 571 and the lower circuit 573, respectively, and the connecting wire 574 is connected to the upper circuit 571 and the first electronic element 511.

### 6th Embodiment

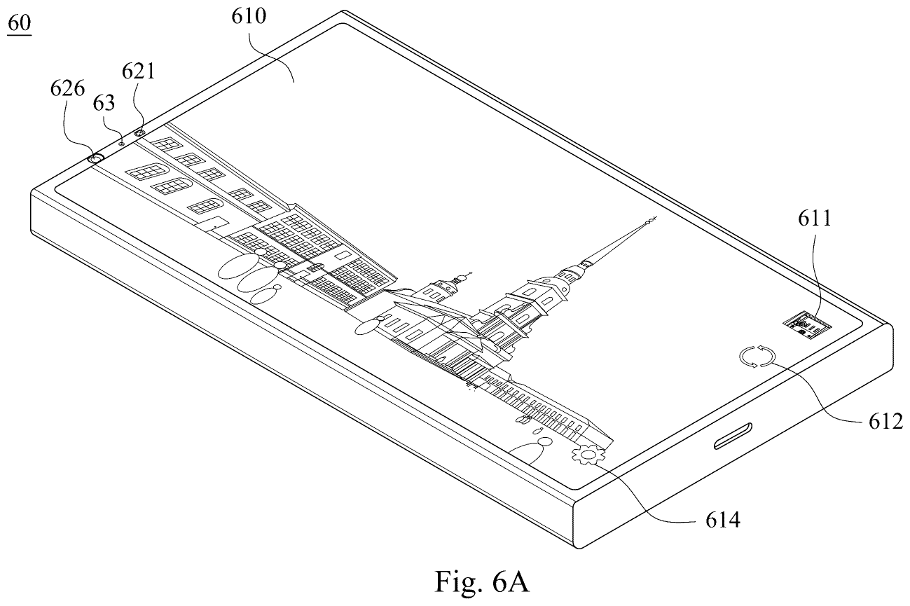

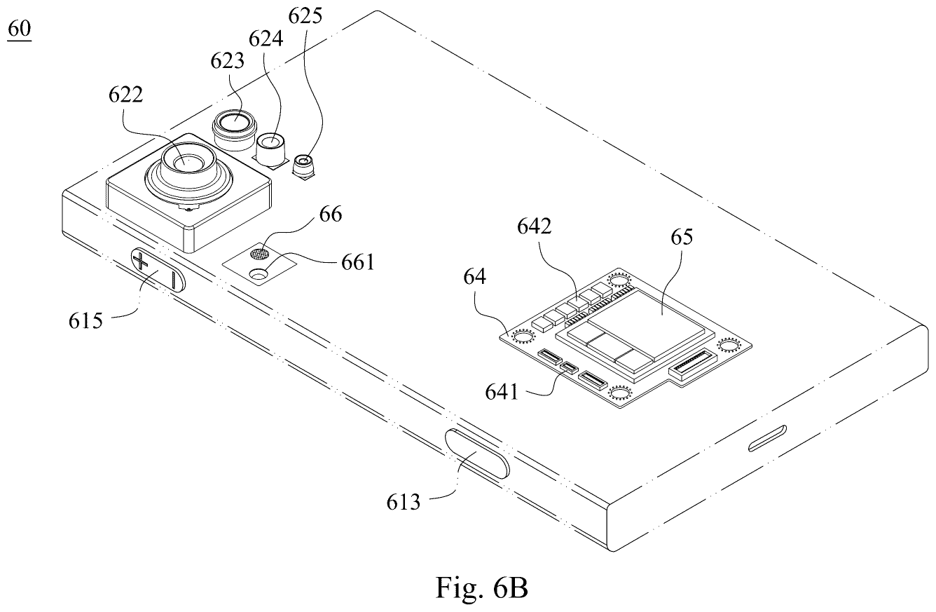

FIG. 6A is a three-dimensional view of an electronic device 60 according to the 6th embodiment of the present disclosure. FIG. 6B is a schematic view of the electronic device 60 according to the 6th embodiment in FIG. 6A. In FIGS. 6A and 6B, the electronic device 60 is a smart phone, wherein the electronic device 60 can also be a laptop, a tablet and a driving recorder, but the present disclosure is not limited thereto. The electronic device 60 includes camera modules and an imaging control interface 610. Furthermore, each of the camera modules can be the camera module according to the aforementioned 1st embodiment to the 5th embodiment, but the present disclosure is not limited thereto.

According to the 6th embodiment, the camera modules are a front camera module 621, a wide angle camera module 622, a telephoto camera module 623, a ultra-wide angle camera module 624, a macro camera module 625 and a Time-Of-Flight (TOF) module 626, wherein the TOF module 626 can be another camera modules with other functions, but the disposition is not limited thereto.

In detail, according to the 6th embodiment, the front camera module 621 and the TOF module 626 are disposed on a front of the electronic device 60, and the wide angle camera module 622, the telephoto camera module 623, the ultra-wide angle camera module 624 and the macro camera module 625 are disposed on a back of the electronic device 60.

The imaging control interface 610 can be a touch screen for displaying the scene and having the touch function, and the shooting angle can be manually adjusted. In detail, the imaging control interface 610 includes an image replay button 611, a camera module switching button 612, a focus capturing button 613, an integrated menu button 614 and a zoom control button 615. Furthermore, users enter a shooting mode via the imaging control interface 610 of the electronic device 60, the camera module switching button 612 can be flexibly configured to switch one of the front camera module 621, the wide angle camera module 622, the telephoto camera module 623, the ultra-wide angle camera module 624 and the macro camera module 625 to capture the image, the zoom control button 615 is configured to adjust the zoom, the users use the focus capturing button 613 to undergo image capturing after capturing the images and confirming one of the front camera module 621, the wide angle camera module 622, the telephoto camera module 623, the ultra-wide angle camera module 624 and the macro camera module 625, the users can view the images by the image replay button 611 after undergoing image capturing, and the integrated menu button 614 is configured to adjust the details of the image capturing (such as timed photo, photo ratio, and etc.).

The electronic device 60 can further include a reminding light 63, and the reminding light 63 is disposed on the front of the electronic device 60 and can be configured to remind the users of unread messages, missed calls and the condition of the phone.

Moreover, after entering the shooting mode via the imaging control interface 610 of the electronic device 60, the imaging light is gathered on the image sensor via the camera module, and an electronic signal about an image is output to an image signal processor (ISP) (its reference numeral is omitted) of a single chip system 65. The single chip system 65 can further include a random access memory (RAM) (its reference numeral is omitted), a central processing unit (its reference numeral is omitted) and a storage unit (its reference numeral is omitted). Also, the single chip system 65 can further include, but not be limited to, a display, a control unit, a read-only memory (ROM), or the combination thereof.

Further, the electronic device 60 can further include an image software processor and an image signal processor, and further integrates the image software processor, the image signal processor, a position locator, a transmit signal processor, a gyroscope, a storage unit and a random access memory in the single chip system 65.

To meet a specification of the electronic device 60, the electronic device 60 can further include an optical anti-shake mechanism (not shown). Furthermore, the electronic device 60 can further include at least one focusing assisting module 66 and at least one sensing element (not shown). The focusing assisting module 66 can include a flash module 661 for compensating a color temperature, an infrared distance measurement component (not shown), a laser focus module (not shown), etc. The sensing element can have functions for sensing physical momentum and kinetic energy, such as an accelerator, a gyroscope, a Hall Effect Element, a position locator, a signal transmitter module, to sense shaking or jitters applied by hands of the user or external environments. Accordingly, the camera modules of the electronic device 60 equipped with an auto-focusing mechanism and the optical anti-shake mechanism can be enhanced to achieve the superior image quality. Furthermore, the electronic device 60 according to the present disclosure can have a capturing function with multiple modes, such as taking optimized selfies, high dynamic range (HDR) under a low light condition, 4K resolution recording, etc. Furthermore, the users can visually see a captured image of the camera through the imaging control interface 610 and manually operate the view finding range on the imaging control interface 610 to achieve the autofocus function of what you see is what you get.

Moreover, the camera module, the optical anti-shake mechanism, the sensing element, the focusing assisting module 66 and an electronic element 642 can be disposed on an electronic element board 64 and electrically connected to the associated components via a connector 641 to perform a capturing process, wherein the electronic element board 64 can be a flexible printed circuit board (FPC). Since the current electronic devices, such as smart phones, have a tendency of being compact, the way of firstly disposing the camera module and related components on the flexible printed circuit board and secondly integrating the circuit thereof into the main board of the electronic device via the connector can satisfy the requirements of the mechanical design and the circuit layout of the limited space inside the electronic device, and obtain more margins. The autofocus function of the camera module can also be controlled more flexibly via the touch screen of the electronic device. According to the 6th embodiment, the sensing element and the focusing assisting module 66 are disposed on the electronic element board 64 and at least one other flexible printed circuit board (not shown) and electrically connected to the associated components, such as the image signal processor, via corresponding connectors to perform the capturing process. In other examples (not shown), the sensing elements and the focusing assisting modules can also be disposed on the main board of the electronic device or carrier boards of other types according to requirements of the mechanical design and the circuit layout.

Moreover, the image of the certain range with the high resolution can be captured via the wide angle camera module 622, and the wide angle camera module 622 has the function of the high resolution and the low deformation. Comparing with the image captured via the wide angle camera module 622, the image captured via the telephoto camera module 623 has narrower visual angle and narrower depth of field. Hence, the telephoto camera module 623 can be configured to capture the moving targets, that is, the telephoto camera module 623 can be driven via an actuator (not shown) of the electronic device 60 to quick and continuous auto focus the moving targets so as to make the image of the moving targets is not fuzzy owing to defocus. Comparing with the image captured via the wide angle camera module 622, the image captured via the ultra-wide angle camera module 624 has wider visual angle and wider depth of field, but the image captured via the ultra-wide angle camera module 624 also has greater distortion.

In particular, the zooming function can be obtained via the electronic device 60, when the scene is captured via the camera modules with different focal lengths cooperated with the function of image processing.

### 7th Embodiment

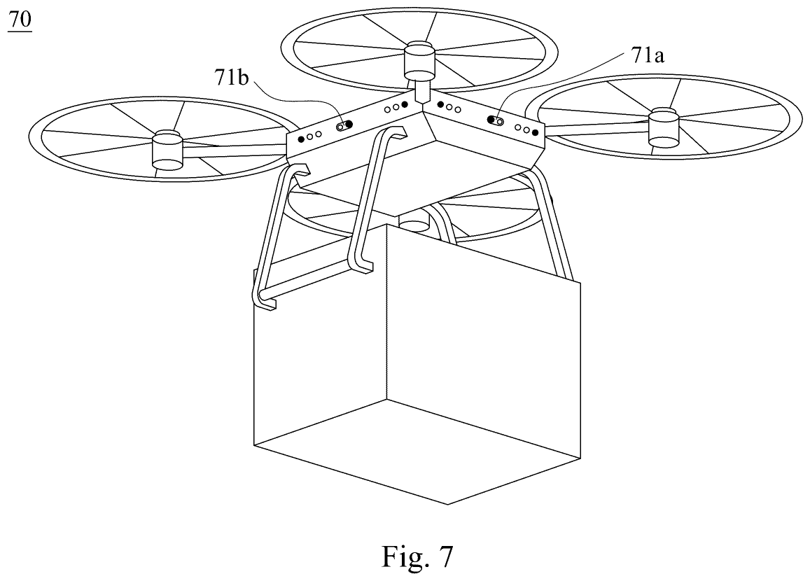

FIG. 7 is a schematic view of an electronic device applied to a drone 70 according to the 7th embodiment of the present disclosure. In FIG. 7, the electronic device (its reference numeral is omitted) includes camera modules. Furthermore, each of the camera modules can be the camera module according to the aforementioned 1st embodiment to the 5th embodiment, but the present disclosure is not limited thereto.

According to the 7th embodiment, the camera modules are a front camera module 71a and a lateral camera module 71b.

In particular, the front camera module 71a is disposed on a front end of the drone 70, and the lateral camera module 71b is disposed on a side of the drone 70. Therefore, the electronic device can be configured to cope with the complicated environmental light.

### 8th Embodiment

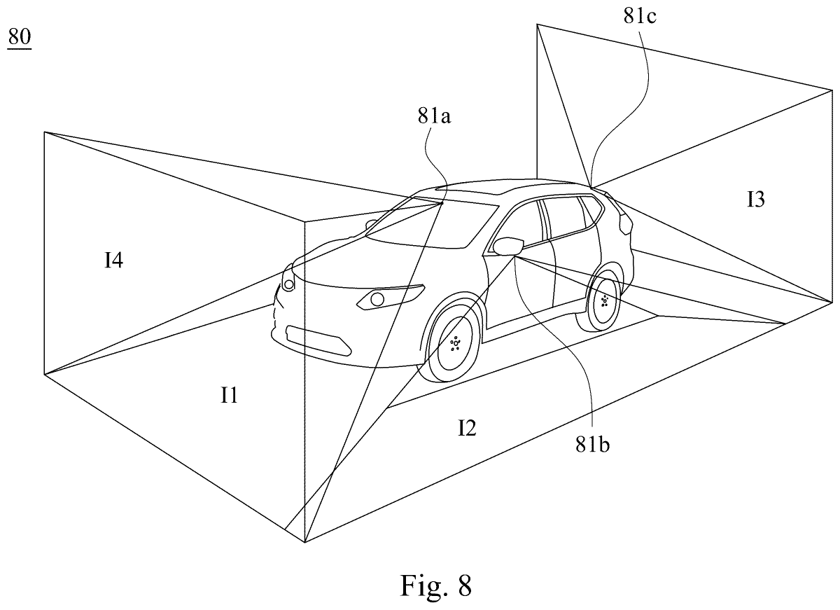

FIG. 8 is a schematic view of an electronic device applied to a car 80 according to the 8th embodiment of the present disclosure. In FIG. 8, the electronic device (its reference numeral is omitted) includes camera modules. Furthermore, each of the camera modules can be the camera module according to the aforementioned 1st embodiment to the 5th embodiment, but the present disclosure is not limited thereto.

According to the 8th embodiment, the camera modules are a front camera module 81a, a lateral camera module 81b and a rear camera module 81c.

In particular, the front camera module 81a, the lateral camera module 81b and the rear camera module 81c are disposed on a front end, a lateral and a rear end of the car 80, respectively, so as to make for the drivers to obtain external space informations in addition to the car 80, such as external space informations 11, 12, 13, 14, but the present disclosure is not limited thereto. Therefore, more visual angles can be provided to reduce the blind spot, so that the driving safety can be improved.

### 9th Embodiment

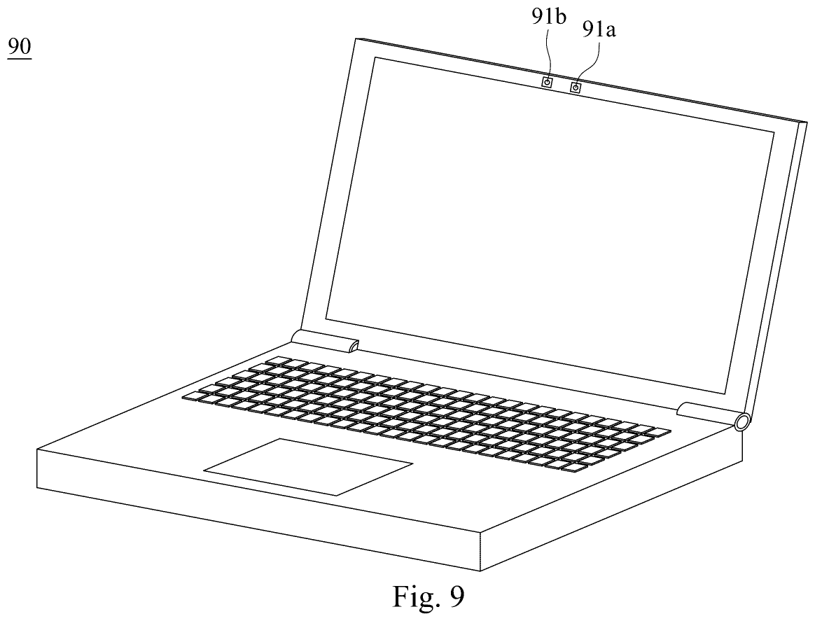

FIG. 9 is a schematic view of an electronic device applied to a computer 90 according to the 9th embodiment of the present disclosure. In FIG. 9, the electronic device (its reference numeral is omitted) includes camera modules. Furthermore, each of the camera modules can be the camera module according to the aforementioned 1st embodiment to the 5th embodiment, but the present disclosure is not limited thereto.

According to the 9th embodiment, the camera modules are a video camera module 91a and an infrared camera module 91b, and both of the video camera module 91a and the infrared camera module 91b are disposed on a front of the computer 90.

### 10th Embodiment

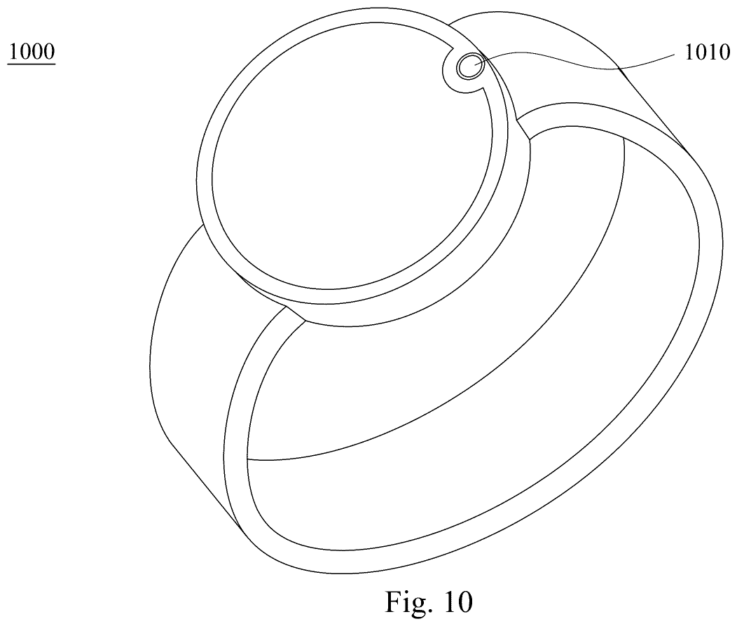

FIG. 10 is a schematic view of an electronic device applied to a wearable device 1000 according to the 10th embodiment of the present disclosure. In FIG. 10, the electronic device (its reference numeral is omitted) includes a camera module. Furthermore, the camera module can be the camera module according to the aforementioned 1st embodiment to the 5th embodiment, but the present disclosure is not limited thereto.

According to the 10th embodiment, the camera module is a video camera module 1010 disposed on a front of the wearable device 1000.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. An electronic element assembly, comprising:
a first electronic element;
an electronic element board, the first electronic element disposed on the electronic element board, and the electronic element board comprising a first circuit and a second circuit, wherein the first circuit and the second circuit are disposed on relative sides of the first electronic element, respectively, and the first circuit is electronically connected to the first electronic element; and
a flexible circuit disposed on the electronic element board, and the flexible circuit comprising:
a connecting portion connected to the electronic element board;
a bending portion disposed on a side of the connecting portion away from the first electronic element, and the bending portion bending along a thickness direction of the electronic element board; and
an electronic path comprising a first end and a second end, and at least one portion of the electronic path disposed on the bending portion, wherein the first end is electronically connected to the first circuit, the second end is electronically connected to the second circuit, and the first end and the second end are disposed on the connecting portion.

2. The electronic element assembly of claim 1, wherein the bending portion and the electronic element board are fixed.

3. The electronic element assembly of claim 2, further comprising:
a hardness reinforcing board disposed on the bending portion, and the hardness reinforcing board and the electronic element board fixed.

4. The electronic element assembly of claim 1, wherein the electronic element board further comprises:
a bend guiding structure correspondingly disposed to a side of the bending portion connected to the connecting portion, and the bending portion bending along the bend guiding structure.

5. The electronic element assembly of claim 1, wherein a dimension of the bending portion on the thickness direction of the electronic element board is less than or equal to a dimension of the bending portion vertical to the thickness direction of the electronic element board and vertical to a thickness direction of the bending portion.

6. The electronic element assembly of claim 1, wherein the bending portion comprises:
a bending auxiliary hole disposed on a side of the bending portion close to the electronic element board, and the electronic path surrounding the bending auxiliary hole;
wherein a dimension of the bending auxiliary hole on the thickness direction of the electronic element board is less than or equal to a dimension of the bending auxiliary hole vertical to the thickness direction of the electronic element board and vertical to a thickness direction of the bending portion.

7. The electronic element assembly of claim 1, further comprising:
a shape maintaining element correspondingly disposed to a side of the bending portion connected to the connecting portion, and the shape maintaining element and the electronic element board fixed.

8. The electronic element assembly of claim 1, wherein the connecting portion of the flexible circuit comprises:
a window relatively disposed to the first electronic element.

9. The electronic element assembly of claim 1, further comprising:
a multilayer circuit board comprising the electronic element board and the flexible circuit, wherein the flexible circuit extends from the electronic element board towards a direction away from the first electronic element.

10. The electronic element assembly of claim 1, wherein the electronic element board further comprises:
an element corresponding hole, wherein the first electronic element is disposed on the element corresponding hole.

11. The electronic element assembly of claim 1, further comprising:
a second electronic element disposed on the electronic element board, and the second electronic element electronically connected to the second circuit;
wherein the electronic element board further comprises a third circuit, and the third circuit is electronically connected to the first electronic element and the second electronic element.

12. The electronic element assembly of claim 1, wherein the electronic element board further comprises a contacting point;
wherein the electronic path comprises a first sub-path and a second sub-path, the first sub-path is electronically connected to the first circuit, the second sub-path is electronically connected to the second circuit, and the first sub-path and the second sub-path are electronically connected via the contacting point.

13. The electronic element assembly of claim 1, wherein the bending portion does not comprise other electronic element.

14. An image sensor module, comprising:
the electronic element assembly of claim 1;
wherein the first electronic element is an image sensor.

15. The image sensor module of claim 14, further comprising:
a holder comprising a through hole;
wherein the through hole is correspondingly disposed to the image sensor, and the bending portion is disposed on the holder.

16. The image sensor module of claim 15, wherein the electronic element assembly further comprises:
a hardness reinforcing board disposed on the bending portion, and the hardness reinforcing board and the holder fixed.

17. The image sensor module of claim 15, wherein the holder further comprises:
a bend guiding structure correspondingly disposed to a side of the bending portion connected to the connecting portion, and the bending portion bending along the bend guiding structure.

18. The image sensor module of claim 14, wherein the connecting portion of the flexible circuit comprises a window relatively disposed to a sensing surface of the image sensor;
wherein the flexible circuit is opaque, the window comprises a plurality of protrusions tapered towards a direction close to the sensing surface, and a length of each of the protrusions along a direction close to the image sensor is between 0.08 mm and 0.43 mm.

19. A camera module, comprising:
the image sensor module of claim 14; and
an imaging lens assembly relatively disposed to the image sensor.

20. The camera module of claim 19, wherein an imaging lens assembly height of the imaging lens assembly is defined from the image sensor towards the thickness direction of the electronic element board, and a bending portion height of the bending portion of the flexible circuit is defined from the image sensor towards the thickness direction of the electronic element board;
wherein the imaging lens assembly height is larger than or equal to the bending portion height.

21. The camera module of claim 19, wherein the electronic element assembly further comprises:
a hardness reinforcing board disposed on the bending portion, and the hardness reinforcing board and the imaging lens assembly fixed.

22. The camera module of claim 19, wherein the imaging lens assembly comprises:
a bend guiding structure correspondingly disposed to a side of the bending portion connected to the connecting portion, and the bending portion bending along the bend guiding structure.

23. The camera module of claim 19, wherein the bending portion of the flexible circuit is opaque, the bending portion comprises a blocking area, the blocking area is disposed on a side of the bending portion away from the connecting portion, and the blocking area is correspondingly disposed to an image height of the imaging lens assembly.

24. An electronic device, comprising:
the camera module of claim 19.

25. An electronic element assembly, comprising:
a first electronic element;
a second electronic element, the first electronic element and the second electronic element disposed at interval;
an electronic element board, the first electronic element and the second electronic element disposed on the electronic element board; and
a flexible circuit disposed on the electronic element board, and the flexible circuit comprising:
a connecting portion connected to the electronic element board;
a bending portion disposed on a side of the connecting portion away from the first electronic element and the second electronic element, and the bending portion bending along a thickness direction of the electronic element board; and
an electronic path comprising a first end and a second end, and at least one portion of the electronic path disposed on the bending portion, wherein the first end is electronically connected to the first electronic element, the second end is electronically connected to the second electronic element, and the first end and the second end are disposed on the connecting portion.

26. The electronic element assembly of claim 25, further comprising:
a hardness reinforcing board disposed on the bending portion, and the hardness reinforcing board and the electronic element board fixed.

27. The electronic element assembly of claim 25, wherein a dimension of the bending portion on the thickness direction of the electronic element board is less than or equal to a dimension of the bending portion vertical to the thickness direction of the electronic element board and vertical to a thickness direction of the bending portion.

28. The electronic element assembly of claim 25, wherein the bending portion comprises:
a bending auxiliary hole disposed on a side of the bending portion close to the electronic element board, and the electronic path surrounding the bending auxiliary hole;
wherein a dimension of the bending auxiliary hole on the thickness direction of the electronic element board is less than or equal to a dimension of the bending auxiliary hole vertical to the thickness direction of the electronic element board and vertical to a thickness direction of the bending portion.

29. The electronic element assembly of claim 25, further comprising:
a multilayer circuit board comprising the electronic element board and the flexible circuit, wherein the flexible circuit extends from the electronic element board towards a direction away from the first electronic element.

30. The electronic element assembly of claim 25, wherein the electronic element board further comprises:
an element corresponding hole, wherein the first electronic element is disposed on the element corresponding hole.

31. An image sensor module, comprising:
the electronic element assembly of claim 25;
wherein the first electronic element is an image sensor.

32. The image sensor module of claim 31, wherein the connecting portion of the flexible circuit comprises a window relatively disposed to a sensing surface of the image sensor;
wherein the flexible circuit is opaque, the window comprises a plurality of protrusions tapered towards a direction close to the sensing surface, and a length of each of the protrusions along a direction close to the image sensor is between 0.08 mm and 0.43 mm.

33. A camera module, comprising:
the image sensor module of claim 31; and
an imaging lens assembly relatively disposed to the image sensor.

34. The camera module of claim 33, wherein an imaging lens assembly height of the imaging lens assembly is defined from the image sensor towards the thickness direction of the electronic element board, and a bending portion height of the bending portion of the flexible circuit is defined from the image sensor towards the thickness direction of the electronic element board;
wherein the imaging lens assembly height is larger than or equal to the bending portion height.

35. An electronic device, comprising:
the camera module of claim 33.
